(19) United States
(12) Patent Application Publication
(10) Pub. No.: US 2026/0114139 A1
(43) Pub. Date: Apr. 23, 2026

(54) DISPLAY PANEL AND ELECTRONIC APPARATUS INCLUDING THE SAME

(71) Applicant: Samsung Display Co., Ltd., Yongin-si (KR)

(72) Inventors: Seongyoung Lee, Yongin-si (KR); Sunkwang Kim, Yongin-si (KR)

(73) Assignee: Samsung Display Co., Ltd., Yongin-si (KR)

(21) Appl. No.: 19/242,136

(22) Filed: Jun. 18, 2025

(30) Foreign Application Priority Data
Oct. 17, 2024 (KR) 10-2024-0142300

(51) Int. Cl. H10K 59/131; H10K 59/123

(52) U.S. Cl. CPC H10K 59/131; H10K 59/123

(57) ABSTRACT

A display panel and an electronic apparatus including the display panel are provided. The display panel includes a pixel circuit including a first color pixel circuit, a second color pixel circuit, and a third color pixel circuit, and a data line set disposed on one side of the pixel circuit, the data line set including a first color data line, a second color data line, and a third color data line each extending in a first direction, wherein, among first color light emitted by the first color pixel circuit, second color light emitted by the second color pixel circuit, and third color light emitted by the third color pixel circuit, the second color light includes highest proportion in white light, and one of the first color data line and the third color data line in the data line set is disposed at a center of the data line set.

### CROSS-REFERENCE TO RELATED APPLICATIONS

This application claims priority to and benefits of Korean Patent Application No. 10-2024-0142300 under 35 U.S.C. § 119, filed on October 17, 2024, in the Korean Intellectual Property Office, the entire contents of which are incorporated herein by reference.

### BACKGROUND

### 1. Technical Field

One or more embodiments relate to a display panel and an electronic apparatus including the display panel, and more particularly, to a display panel and an electronic apparatus, which are capable of displaying high-quality images.

### 2. Description of the Related Art

Generally, a display apparatus includes thin-film transistors, connection electrodes, and wirings in each pixel (or each sub-pixel) to control the luminance or the like of each pixel (or each sub-pixel). The thin-film transistors, the connection electrodes, and the wiring form a multi-layered structure.

### SUMMARY

The luminance of some pixels of a display apparatus of the related art may be unintentionally changed.

One or more embodiments include a display panel and an electronic apparatus including the display panel, which are capable of displaying high-quality images. However, aspects of embodiments are not limited thereto, and the above characteristics do not limit the scope of embodiments according to the disclosure.

Additional aspects will be set forth in part in the description which follows and, in part, will be apparent from the description, or may be learned by practice of the presented embodiments of the disclosure.

According to one or more embodiments, a display panel includes a pixel circuit including a first color pixel circuit, a second color pixel circuit, and a third color pixel circuit, and a data line set disposed on one side of the pixel circuit and including a first color data line, a second color data line, and a third color data line each extending in a first direction, wherein, among first color light emitted by the first color pixel circuit, second color light emitted by the second color pixel circuit, and third color light emitted by the third color pixel circuit, the second color light includes highest proportion in white light, and one of the first color data line and the third color data line in the data line set is disposed at a center of the data line set.

Among the first color data line, the second color data line, and the third color data line, the second color data line may be disposed closest to the pixel circuit.

The second color data line may include a plurality of protrusions that protrude in a direction crossing the first direction in a portion corresponding to the pixel circuit.

The third color light may include lowest proportion in the white light, one of the plurality of protrusions may be disposed to overlap the second color pixel circuit, and another one of the plurality of protrusions may be disposed to overlap the third color pixel circuit.

The second color data line may include two protrusions protruding in a direction crossing the first direction in a portion corresponding to the pixel circuit.

The third color light may include lowest proportion in the white light, one of the two protrusions of the second color data line may be disposed to overlap the second color pixel circuit, and the other of the two protrusions of the second color data line may be disposed to overlap the third color pixel circuit.

The first color pixel circuit may include a first color data connection line electrically connecting a thin film transistor of the first color pixel circuit to the first color data line, the second color pixel circuit may include a second color data connection line electrically connecting a thin film transistor of the second color pixel circuit to the second color data line, and the third color pixel circuit may include a third color data connection line electrically connecting a thin film transistor of the third color pixel circuit to the third color data line.

The third color light may include lowest proportion in the white light, the first color pixel circuit may include a first color data connection line electrically connecting a thin film transistor of the first color pixel circuit to the first color data line, the second color pixel circuit may include a second color data connection line electrically connecting a thin film transistor of the second color pixel circuit to the second color data line, and the third color pixel circuit may include a third color data connection line electrically connecting a thin film transistor of the third color pixel circuit to the second color data line.

The display panel may further include a dummy electrode on a layer on which the third color data connection line is disposed, having an isolated shape, and electrically connected to the third color data line.

The display panel may further include a first color pixel electrode electrically connected to the first color pixel circuit, a second color pixel electrode electrically connected to the second color pixel circuit, and an additional connection electrode electrically connected to the third color pixel circuit and the second color pixel electrode.

The display panel may further include a third color pixel electrode on a layer on which the additional connection electrode is disposed, spaced apart from the additional connection electrode, and having an isolated shape.

In a plan view, the second color pixel electrode may be closer to the third color pixel electrode than to the first color pixel electrode.

The additional connection electrode may be disposed between the second color pixel electrode and the third color pixel electrode.

Among the first color data line, the second color data line, and the third color data line, the second color data line may be disposed farthest from the pixel circuit.

The first color pixel circuit may include a first color data connection line electrically connecting a thin film transistor of the first color pixel circuit to the first color data line, the second color pixel circuit may include a second color data connection line electrically connecting a thin film transistor of the second color pixel circuit to the second color data line, and the third color pixel circuit may include a third color data connection line electrically connecting a thin film transistor of the third color pixel circuit to the third color data line, and a dummy connection line electrically connected to the thin film transistor of the third color pixel circuit and extending over the second color data line.

The third color light may include lowest proportion in the white light, the first color pixel circuit may include a first color data connection line electrically connecting a thin film transistor of the first color pixel circuit to the first color data line, the second color pixel circuit may include a second color data connection line electrically connecting a thin film transistor of the second color pixel circuit to the second color data line, and the third color pixel circuit may include a dummy connection line electrically connecting a thin film transistor of the third color pixel circuit to the second color data line.

The display panel may further include a third color data connection line on a layer on which the dummy connection line is disposed, having an isolated shape, and electrically connected to the third color data line.

The display panel may further include a first color pixel electrode electrically connected to the first color pixel circuit, a second color pixel electrode electrically connected to the second color pixel circuit, and an additional connection electrode electrically connected to the third color pixel circuit and the third color pixel electrode.

The display panel may further include a third color pixel electrode on a layer on which the additional connection electrode is disposed, spaced apart from the additional connection electrode, and having an isolated shape.

In a plan view, the second color pixel electrode may be disposed closer to the third color pixel electrode than to the first color pixel electrode.

The additional connection electrode may be disposed between the second color pixel electrode and the third color pixel electrode.

The first color light may include red light, the second color light may include green light, and the third color light may include blue light.

According to one or more embodiments, an electronic apparatus may include

a display panel including: a pixel circuit including a first color pixel circuit, a second color pixel circuit, and a third color pixel circuit; and a data line set disposed on one side of the pixel circuit and including a first color data line, a second color data line, and a third color data line each extending in a first direction, wherein, among first color light emitted by the first color pixel circuit, second color light emitted by the second color pixel circuit, and third color light emitted by the third color pixel circuit, the second color light includes highest proportion in white light, and one of the first color data line and the third color data line in the data line set is disposed at a center of the data line set and a lower cover forming an exterior of the electronic apparatus and having an opening exposing a portion of the display panel.

Other aspects, features and advantages other than those described above will become apparent from the following detailed description, claims and drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view illustrating a portion of a display panel according to an embodiment;

FIG. 2 is a schematic conceptual diagram illustrating a portion of the display panel of FIG. 1;

FIG. 3 is a schematic diagram of an equivalent circuit of a display element and a pixel circuit electrically connected to the display element of the display panel of FIG. 1;

FIG. 4 is a schematic layout diagram illustrating locations of thin film transistors and a storage capacitor, etc. in one pixel of the display panel of FIG. 1;

FIGS. 5 through 8 are schematic layout diagrams illustrating, on a layer-by-layer basis, components such as thin film transistors and a storage capacitor of the display panel of FIG. 4;

FIG. 9 is a schematic cross-sectional view of the display panel taken along line A-A' of FIG. 4;

FIGS. 10 and 11 are schematic layout diagrams illustrating some layers of components such as thin film transistors and a storage capacitor of a display panel according to an embodiment;

FIGS. 12 and 13 are schematic layout diagrams illustrating some layers of components such as thin film transistors and a storage capacitor of a display panel according to an embodiment;

FIG. 14 is a schematic layout diagram illustrating some layers of components such as thin film transistors and a storage capacitor of a display panel according to an embodiment;

FIG. 15 is a schematic conceptual diagram illustrating an image which a display panel may display;

FIG. 16 is a schematic graph illustrating data signals applied to the display panel to display the image of FIG. 15;

FIG. 17 is a schematic conceptual diagram illustrating an electronic apparatus according to an embodiment; and

FIG. 18 is a schematic block diagram illustrating the electronic apparatus of FIG. 17.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element’s relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

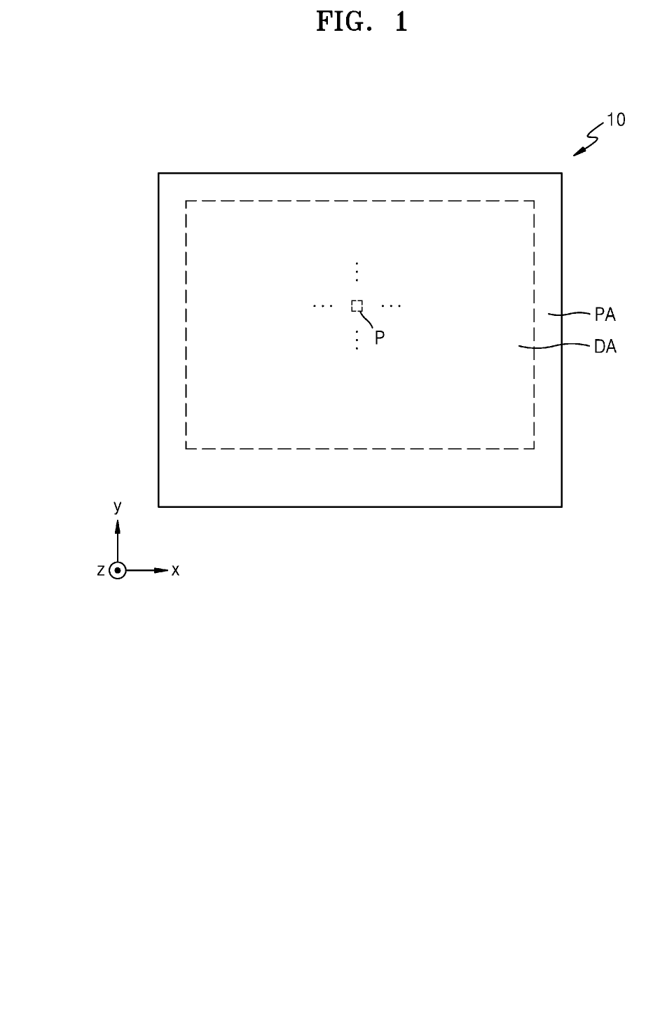

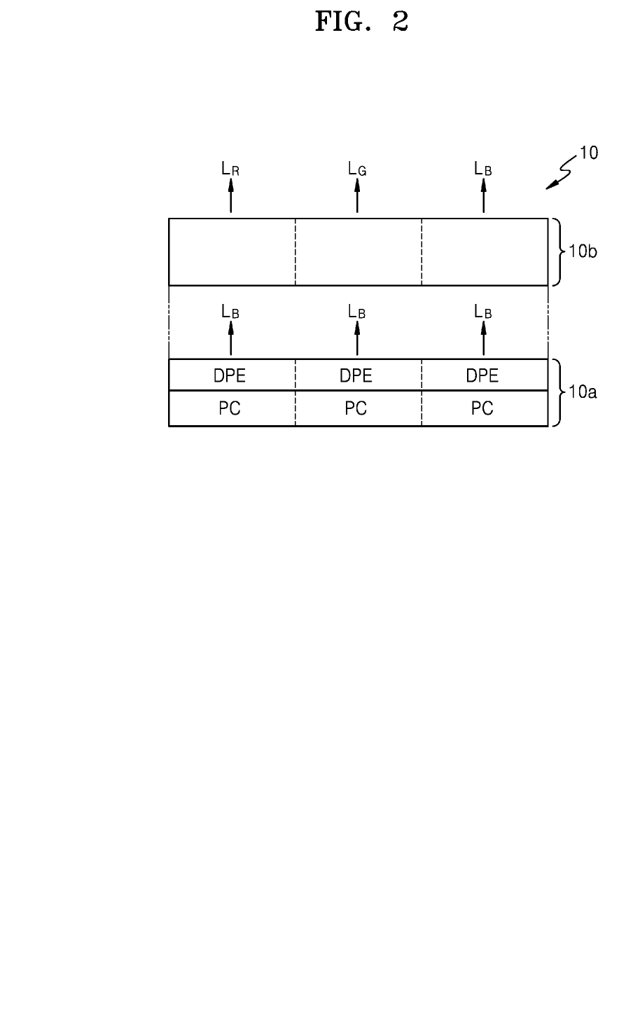

FIG. 1 is a schematic plan view illustrating a portion of a display panel 10 according to an embodiment and FIG. 2 is a schematic conceptual diagram illustrating a portion of the display panel 10 of FIG. 1.

As shown in FIG. 1, the display panel 10 may include a display area DA, in which multiple pixels P are arranged, and a peripheral area PA located outside the display area DA. The peripheral area PA may surround (or completely surround) the display area DA.

The display area DA may have a polygon shape, such as a quadrangle as shown in FIG. 1. For example, the display area DA may have a rectangular shape with a horizontal length greater than a vertical length, a rectangular shape with a horizontal length less than a vertical length, or a square shape. In another embodiment, the display area DA may have any of various shapes such as an oval, a circle, or a polygonal shape other than a rectangular shape.

As shown in FIG. 2, the display panel 10 may include a light-emitting panel 10a and a filter panel 10b stacked on each other. The light-emitting panel 10a may include multiple display elements DPE, wherein each of the display elements DPE is electrically connected to a circuit PC (hereinafter, referred to as a pixel circuit PC) corresponding thereto. The display elements DPE and the pixel circuits PC may be arranged in the display area DA.

The display area DA may provide a predetermined image by using light emitted by the display elements DPE. For example, blue light L_{B} emitted by the display elements DPE may be converted into red light L_{R} and green light L_{G} while passing through the filter panel 10b or may pass through the filter panel 10b without being converted. To this end, the filter panel 10b may include a quantum dot layer which converts the blue light L_{B} incident on the quantum dot layer into the red light L_{R}, a quantum dot layer which converts the blue light L_{B} incident on the quantum dot layer into the green light L_{G}, or a light-transmitting layer through which the blue light L_{B} incident on the light-transmitting layer passes. The display panel 10 may provide a predetermined image by using light converted by the filter panel 10b or light passing through the filter panel 10b without being converted, for example, the red light L_{R}, the green light L_{G}, and the blue light L_{B}.

However, embodiments are not limited thereto. For example, the display panel 10 may provide a predetermined image using light only from the light-emitting panel 10a. For example, the light-emitting panel 10a may emit the red light L_{R}, the green light L_{G}, and the blue light L_{B}.

The peripheral area PA is a non-display area that provides no images, and may completely or partially surround the display area DA. A driver or a main power line for providing an electrical signal or power to the pixel circuits PC may be arranged in the peripheral area PA. The peripheral area PA may include a pad to which an electronic apparatus or a printed circuit board (PCB) may be electrically connected.

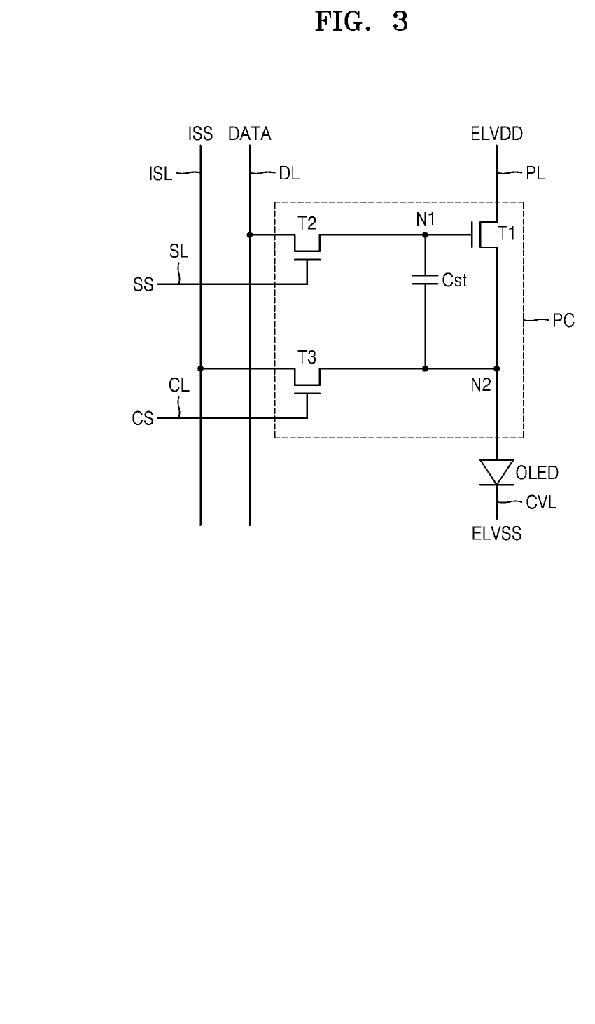

FIG. 3 is a schematic diagram of an equivalent circuit of a display element DPE and a pixel circuit PC electrically connected to the display element DPE of the display panel 10 of FIG. 1. In FIG. 3, an organic light-emitting diode OLED, which is the display element DPE, is electrically connected to the pixel circuit PC. A pixel electrode of the organic light-emitting diode OLED may be electrically connected to the pixel circuit PC, and an opposite electrode of the organic light-emitting diode OLED may be electrically connected to a common voltage line CVL providing a common power supply voltage ELVSS. The organic light-emitting diode OLED may emit light with a brightness corresponding to a current amount provided by the pixel circuit PC.

The pixel circuit PC may include a first transistor T1, a second transistor T2, a third transistor T3, and a storage capacitor Cst. Each of the first transistor T1, the second transistor T2, and the third transistor T3 may be an oxide semiconductor thin-film transistor including a semiconductor layer formed of an oxide semiconductor, or may be a silicon semiconductor thin-film transistor including a semiconductor layer formed of polysilicon.

The first transistor T1 may be a driving transistor. One end of the first transistor T1 may be electrically connected to the pixel electrode of the organic light-emitting diode OLED, and another end of the first transistor T1 may be electrically connected to a power line PL that supplies a driving power supply voltage ELVDD. A driving gate electrode of the first transistor T1 may be electrically connected to a first node N1. The first transistor T1 may control a current amount flowing from the power line PL to the organic light-emitting diode OLED in accordance with a voltage of the first node N1.

The second transistor T2 may be a switching transistor. One end of the second transistor T2 may be electrically connected to a data line DL, and another end of the second transistor T2 may be electrically connected to the first node N1. A switching gate electrode of the second transistor T2 may be electrically connected to a scan line SL. The second transistor T2 may be turned on in case that a scan signal SS is supplied to the scan line SL, and may electrically connect the data line DL to the first node N1 to transmit a data signal DATA from the data line DL to the first node N1.

The third transistor T3 may be an initialization-sensing transistor. One end of the third transistor T3 may be electrically connected to an initialization-sensing line ISL, and another end of the third transistor T3 may be electrically connected to a second node N2. An initialization gate electrode of the third transistor T3 may be electrically connected to a control line CL.

The third transistor T3 may be turned on in case that a control signal CS is supplied to the control line CL, and may electrically connect the initialization-sensing line ISL to the second node N2 to transmit an initialization-sensing signal ISS from the initialization-sensing line ISL to the second node N2. For example, in case that the third transistor T3 is turned on, the third transistor T3 may initialize the potential of a pixel electrode of the organic light-emitting diode OLED by using the initialization-sensing signal ISS from the initialization-sensing line ISL as an initialization voltage. In another embodiment, in case that the third transistor T3 is turned on, the third transistor T3 may sense property information of the organic light-emitting diode OLED. For example, the third transistor T3 may include both a function as an initialization transistor as described above and a function as a sensing transistor as described above, or may include one of the two functions. In case that the third transistor T3 includes the function as the initialization transistor, the initialization-sensing line ISL may be regarded as an initializing voltage line, and, in case that the third transistor T3 includes the function as the sensing transistor, the initialization-sensing line ISL may be regarded as a sensing line. An initialization operation and a sensing operation of the third transistor T3 may be individually conducted or may be simultaneously conducted. For example, the third transistor T3 may be an initialization transistor and/or a sensing transistor. For convenience of descriptions, a case where the third transistor T3 has both the function of the initialization transistor and the function of the sensing transistor will be described in detail.

The storage capacitor Cst may be connected between the first node N1 and the second node N2. For example, one capacitor electrode of the storage capacitor Cst may be electrically connected to the driving gate electrode of the first transistor T1, and the other capacitor electrode of the storage capacitor Cst may be electrically connected to the pixel electrode of the organic light-emitting diode OLED.

FIG. 3 shows that the pixel circuit PC includes three transistors T1 through T3 and one storage capacitor Cst, however, the embodiments are not limited thereto. For example, the number of transistors or storage capacitors included in the pixel circuit PC may vary.

FIG. 3 shows that the display element DPE is the organic light-emitting diode OLED including an organic material, however, embodiments are not limited thereto. For example, the display element DPE may be an inorganic light-emitting diode including an inorganic material. The inorganic light-emitting diode may include a PN diode including materials based on an inorganic material semiconductor. In case that a voltage is applied to the PN junction diode in a forward direction, holes and electrons are injected, and energy generated by recombination of the holes and the electrons is converted into light energy to thereby emit light of a predetermined color. Such an inorganic light-emitting diode may have a width of several to several hundreds of micrometers. The inorganic light-emitting diode may be referred to as a micro-LED.

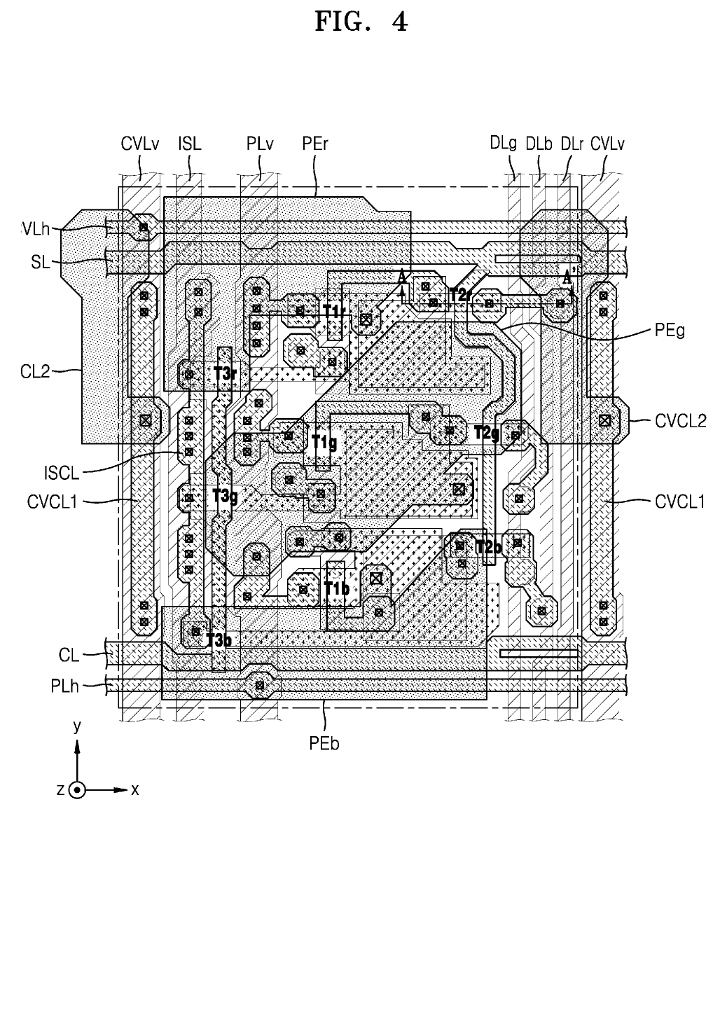

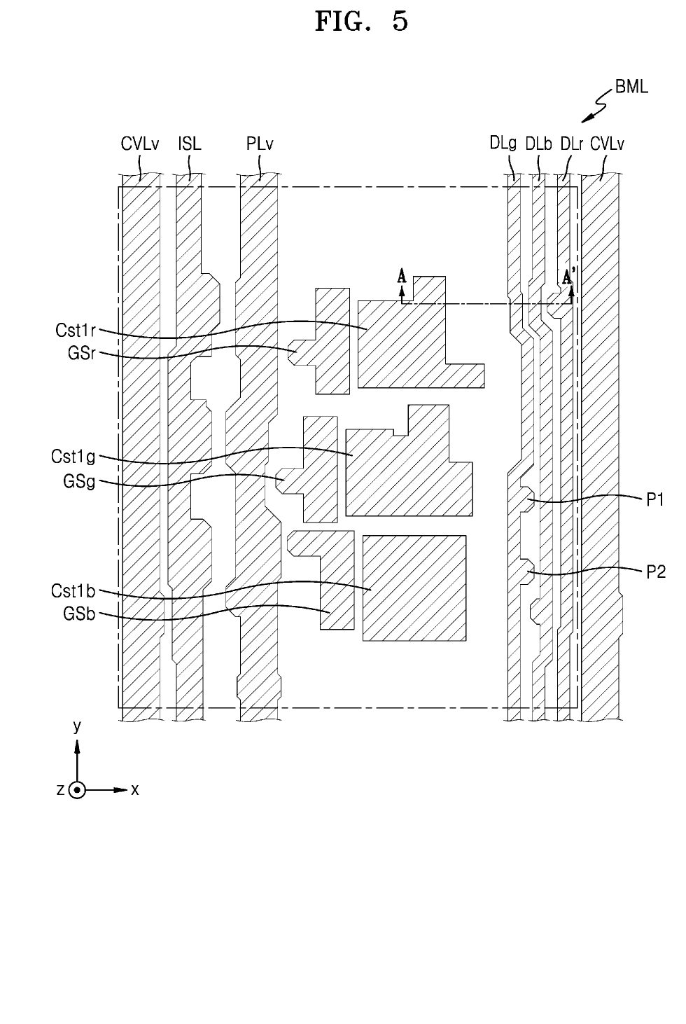

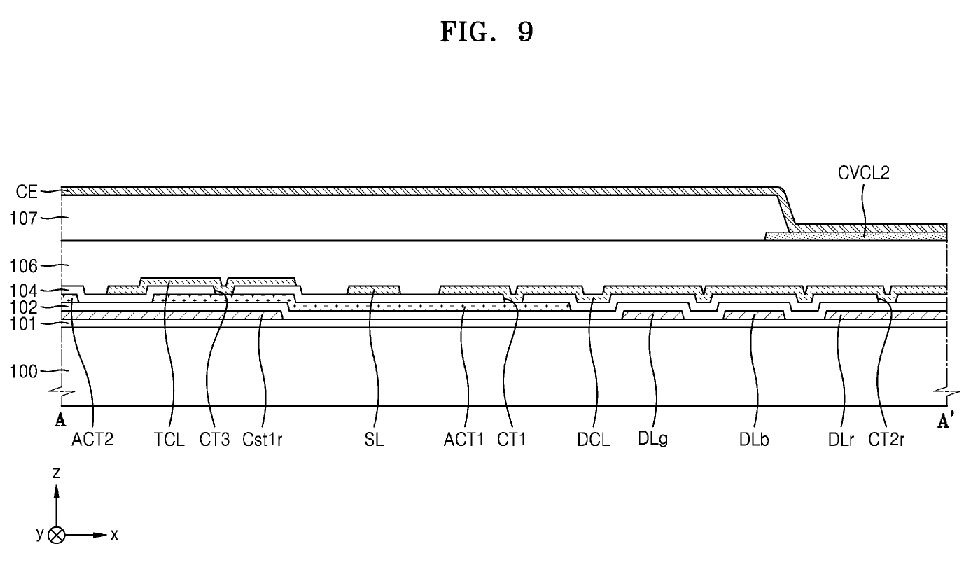

FIG. 4 is a schematic layout diagram illustrating locations of transistors and a storage capacitor Cst in one pixel of the display panel 10 of FIG. 1, FIGS. 5 through 8 are schematic layout diagrams illustrating, on a layer-by-layer basis, components such as the transistors and the storage capacitor Cst of the display panel 10 of FIG. 4, and FIG. 9 is a schematic cross-sectional view of the display panel 10 taken along line A-A' of FIG. 4. For reference, one pixel may include multiple sub-pixels, for example, three sub-pixels, and accordingly, the above-described equivalent circuit diagram of FIG. 3 is an equivalent circuit diagram of one sub-pixel. FIG. 4 schematically illustrates positions of transistors and storage capacitors Cst in one pixel including three subpixels.

As shown in FIGS. 4 through 8, one pixel may include three sub-pixels. FIG. 4 shows a case in which one pixel includes a red subpixel, a green subpixel, and a blue subpixel. The red subpixel may include one storage capacitor Cst including a first capacitor electrode Cst1r (see FIG. 5) and three transistors T1r, T2r, and T3r, the green subpixel may include one storage capacitor Cst including a first capacitor electrode Cst1g (see FIG. 5) and three transistors T1g, T2g, and T3g, and the blue subpixel may include one storage capacitor Cst including a first capacitor electrode Cst1b (see FIG. 5) and three transistors T1b, T2b, and T3b. Components of the green subpixel and components of the blue subpixel are identical to and/or similar to components of the red subpixel. Accordingly, for convenience of descriptions, the components of the red subpixel will now be focused on and described. This description is equally applicable to the components of the green subpixel and the components of the blue subpixel.

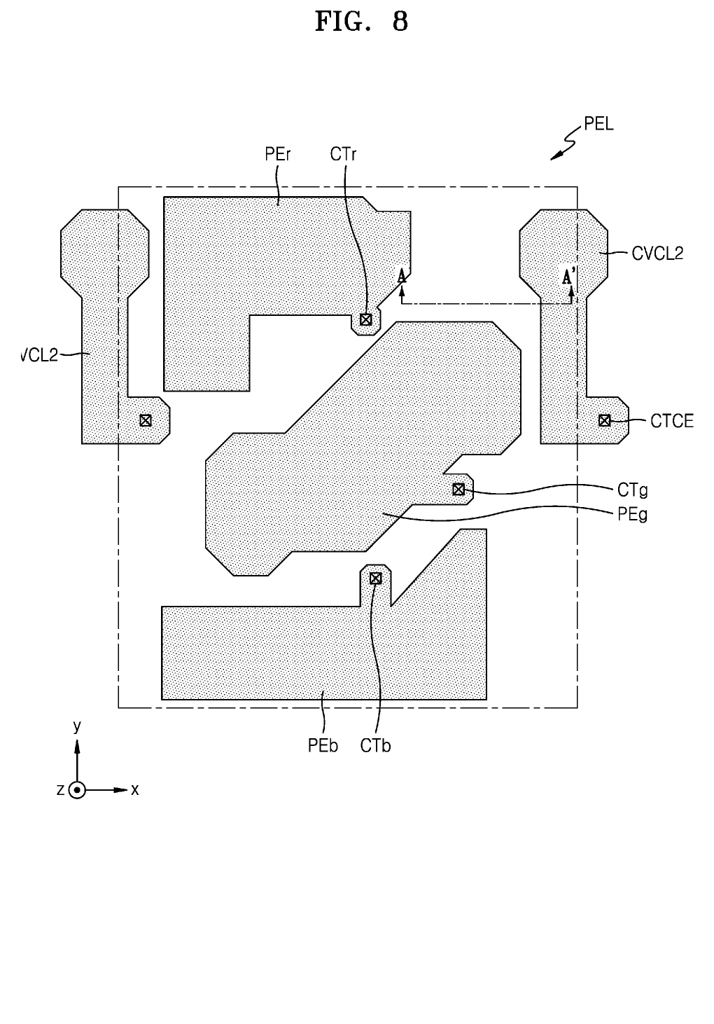

The red subpixel may include a red pixel circuit and a red pixel electrode PEr (see FIG. 8) electrically connected thereto. The red pixel circuit may include one storage capacitor Cst including a first capacitor electrode Cst1r arranged in the red subpixel and three transistors T1r, T2r, and T3r. Similarly, the green subpixel may include a green pixel circuit and a green pixel electrode PEg (see FIG. 8) electrically connected thereto. The green pixel circuit may include one storage capacitor Cst including a first capacitor electrode Cst1g arranged in the green subpixel and three transistors T1g, T2g, and T3g. In the case of the blue subpixel, it may also include a blue pixel circuit and a blue pixel electrode PEb (see FIG. 8) electrically connected thereto. The blue pixel circuit may include one storage capacitor Cst including a first capacitor electrode Cst1b arranged in the blue subpixel and three transistors T1b, T2b, and T3b. The portion indicated by a dashed-dotted line in FIGS. 4 through 8 represents one pixel, and a set of the red pixel circuit, the green pixel circuit, and the blue pixel circuit included in this one pixel may be referred to as a pixel circuit.

The display panel 10 may include a substrate 100 (see FIG. 9), and various components, such as the transistors T1r, T2r, and T3r and the storage capacitor Cst, may be on the substrate 100. The substrate 100 may include glass, metal, or polymer resin. In case that the substrate 100 is flexible or bendable, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including a polymer resin and a barrier layer including an inorganic material (silicon oxide, silicon nitride, silicon oxynitride, or the like) and located between the two layers. For example, various modifications may be made.

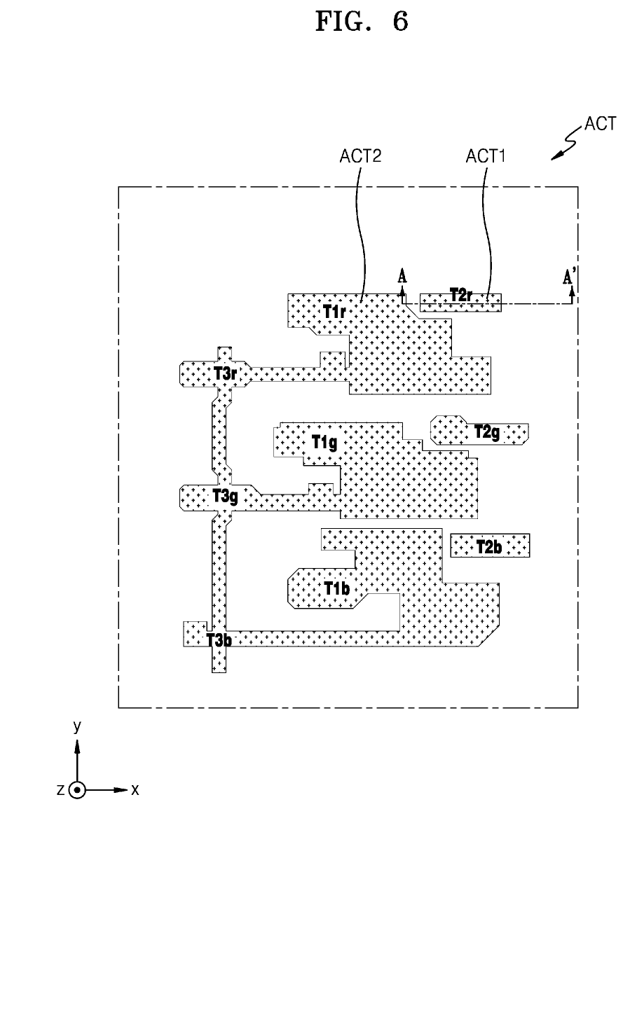

A first buffer layer 101 (see FIG. 9) including an inorganic insulating material, such as silicon oxide, silicon nitride, silicon oxynitride, or aluminum oxide, may be positioned on the substrate 100. The first buffer layer 101 may prevent metal atoms, impurities, or the like from the substrate 100 from being diffused into an active layer ACT (see FIG. 6) disposed thereover.

A bottom metal layer BML as shown in FIG. 5 may be disposed on the first buffer layer 101. The bottom metal layer BML may include various signal lines, and may serve to protect the active layer ACT disposed thereon by overlapping at least a portion of the active layer ACT. In case that the active layer ACT includes polysilicon, the bottom metal layer BML may control a heat supply rate during a crystallization process for forming the active layer ACT such that the active layer ACT may be uniformly crystallized. The bottom metal layer BML may include a metal, an alloy, a conductive metal oxide, or a transparent conductive material, for example. For example, the bottom metal layer BML may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The bottom metal layer BML may have a multi-layered structure. For example, the bottom metal layer BML may have a double-layer structure of Mo/Al or Ti/Al or a three-layered structure of Ti/Al/Ti.

As shown in FIG. 5, the bottom metal layer BML may include a vertical common voltage line CVLv, an initialization-sensing line ISL, a vertical power line PLv, a blue data line DLb, a green data line DLg, a red data line DLr, first capacitor electrodes Cst1r, Cst1g, and Cst1b, and driving gate electrode shields GSr, GSg, and GSb. Each of the vertical common voltage line CVLv, the initialization-sensing line ISL, the vertical power line PLv, the blue data line DLb, the green data line DLg, and the red data line DLr may extend in a first direction (or y-axis direction). The vertical common voltage line CVLv, the initialization-sensing line ISL, the vertical power line PLv, the blue data line DLb, the green data line DLg, and the red data line DLr may be sequentially arranged in a second direction (or x-axis direction) crossing the first direction (or y-axis direction).

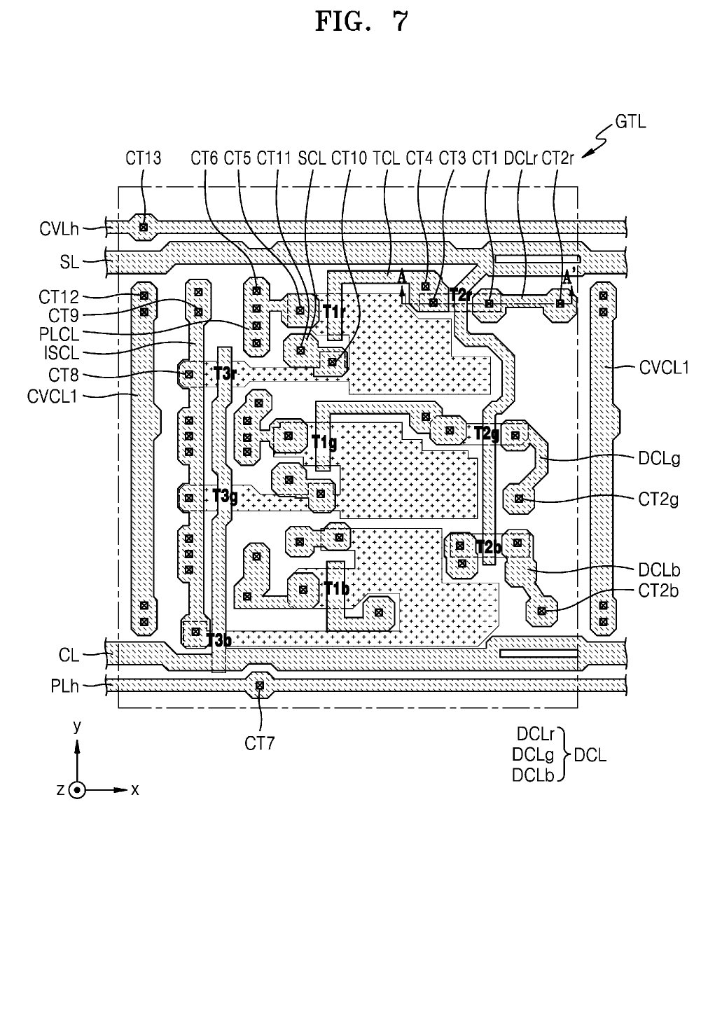

The vertical common voltage line CVLv may extend in the first direction (or y-axis direction) as described above. The vertical common voltage line CVLv may be electrically connected to a horizontal common voltage line CVLh (refer to FIG. 7) extending in the second direction (or x-axis direction), which will be described at a later time. Accordingly, the common voltage line CVL including the vertical common voltage line CVLv and the horizontal common voltage line CVLh electrically connected to each other may have a substantially lattice shape in the display area DA, and thus may have a potential corresponding to the common power supply voltage ELVSS which is substantially uniform in the display area DA. The common voltage line CVL may be electrically connected to a common electrode CE (see FIG. 9), which is an upper electrode of the organic light-emitting diode so that the common electrode CE has a uniform potential in the display area DA.

The initialization-sensing line ISL may extend in the first direction (or y-axis direction). The initialization-sensing line ISL may be electrically connected to a first portion of each of the third transistors T3r, T3g, and T3b, which are initialization-sensing transistors so that, in case that the third transistors T3r, T3g, and T3b are turned on, the initialization-sensing signal ISS from the initialization-sensing line ISL may be transmitted to a red pixel electrode PEr, a green pixel electrode PEg, or a blue pixel electrode PEb.

The vertical power line PLv may extend in the first direction (or y-axis direction) as described above. The vertical power line PLv may be electrically connected to a horizontal power line PLh (see FIG. 7) extending in the second direction (or x-axis direction), which will be described at a later time. Accordingly, the power line PL including the vertical power line PLv and the horizontal power line PLh electrically connected to each other may have a substantially lattice shape in the display area DA, and thus may have a potential of the power supply voltage ELVDD which is substantially uniform in the display area DA. The power line PL may be electrically connected to each of the first transistors T1r, T1g, and T1b, which are driving transistors, and may serve to apply the power supply voltage ELVDD to the first transistors T1r, T1g, and T1b.

Each of the green data line DLg, the blue data line DLb, and the red data line DLr may extend in the first direction (or y-axis direction) as described above. The green data line DLg may be electrically connected to a first portion of the second transistor T2g of the green subpixel, the blue data line DLb may be electrically connected to a first portion of the second transistor T2b of the blue subpixel, and the red data line DLr may be electrically connected to a first portion of the second transistor T2r of the red subpixel. In case that the second transistor T2r of the red subpixel, the second transistor T2g of the green subpixel, and the second transistor T2b of the blue subpixel are turned on by the scan line SL (see FIG. 7), the second transistor T2r of the red subpixel, the second transistor T2g of the green subpixel, and the second transistor T2b of the blue subpixel may transmit the data signal DATA from the red data line DLr, the green data line DLg, and the blue data line DLb to a driving gate electrode of the first transistor T1r of the red subpixel, a driving gate electrode of the first transistor T1g of the green subpixel, and a driving gate electrode of the first transistor T1b of the blue subpixel.

As described above, a portion indicated by a dashed-dotted line in FIGS. 4 through 8 represents one pixel, and the set of the red pixel circuit, the green pixel circuit, and the blue pixel circuit included in this one pixel may be referred to as the pixel circuit. A set of the green data line DLg, the blue data line DLb, and the red data line DLr may be referred to as a data line set, and the data line set may be located on one side of the pixel circuit. FIGS. 4 through 8 show that the data line set is located on one side of the pixel circuit, in the +x direction, to which the data line set is electrically connected. One of the red data line DLr and the blue data line DLb in the data line set may be located at a center in the data line set. FIGS. 4 and 5 shows that the blue data line DLb is located at the center of the data line set. For example, the blue data line DLb may be located between the green data line DLg and the red data line DLr. Accordingly, the green data line DLg may not be located between the red data line DLr and the blue data line DLb.

In case that the display panel 10 and the electronic apparatus including the display panel 10 display a white image, the proportion of the blue light in the white light may be about 10%, the proportion of the red light in the white light may be about 20%, and the proportion of the green light in the white light may be about 70%. Therefore, a viewer (or user) may be sensitive to the change of the amount of the green light. If the green data line DLg is located between the red data line DLr and the blue data line DLb, the green data line DLg may be affected by the red data line DLr and/or the blue data line DLb duet to an electrical coupling, etc., and as a result, the display panel 10 and the electronic apparatus including the display panel 10 may not be able to display a high-quality image.

However, in the case of the display panel 10 and the electronic apparatus including the display panel 10 according to an embodiment, one of the red data line DLr and the blue data line DLb in the data line set is located at the center of the data line set, and thus the green data line DLg may not be located between the red data line DLr and the blue data line DLb. Accordingly, the display panel 10 and the electronic apparatus including the display panel 10, in which a high-quality image is displayed, may be implemented. This will be described later in more detail.

The first capacitor electrodes Cst1r, Cst1g, and Cst1b and the driving gate electrode shields GSr, GSg, and GSb may be located between a set of the vertical common voltage line CVLv, the initialization-sensing line ISL, and the vertical power line PLv and the data line set of the blue data line DLb, the green data line DLg, and the red data line DLr. In a plan view, each of the first capacitor electrodes Cst1r, Cst1g, and Cst1b and each of the driving gate electrode shields GSr, GSg, and GSb may have isolated shapes.

Each of the first capacitor electrodes Cst1r, Cst1g, and Cst1b may be one capacitor electrode of the storage capacitor Cst. Each of the driving gate electrode shields GSr, GSg, and GSb may overlap at least a portion of a corresponding transistor connection line among transistor connection lines TCL (see FIG. 7), which may be considered driving gate electrodes, and thus may protect the active layer ACT disposed over the driving gate electrode shields GSr, GSg, and GSb.

A second buffer layer 102 (see FIG. 9) may be disposed on the first buffer layer 101 to cover the bottom metal layer BML. The second buffer layer 102 may include an insulating material. For example, the second buffer layer 102 may include an inorganic insulating material such as silicon oxide, silicon nitride, silicon oxynitride, or aluminum oxide.

The active layer ACT shown in FIG. 6 may be disposed over the second buffer layer 102. The active layer ACT may include polysilicon or may include an oxide semiconductor. The oxide semiconductor may include Zn oxide, In-Zn oxide, or Ga-In-Zn oxide, as a Zn oxide-based material. In another embodiment, the oxide semiconductor may include an In-Ga-Zn-O (IGZO), In-Sn-Zn-O (ITZO), or In-Ga-Sn-Zn-O (IGTZO) containing metals, such as In, Ga, and Sn, in ZnO. For convenience, a case in which the active layer ACT includes the oxide semiconductor will now be described.

The active layer ACT may include a first active layer ACT1 and a second active layer ACT2. The first active layer ACT1 of the red subpixel, the first active layer ACT1 of the green subpixel, and the first active layer ACT1 of the blue subpixel may be spaced apart from each other, whereas the second active layer ACT2 of the red subpixel, the second active layer ACT2 of the green subpixel, and the second active layer ACT2 of the blue subpixel may be electrically connected to each other and integrally formed as a single body.

Each of the first active layers ACT1 may have a shape extending in the second direction (or x-axis direction) to cross a portion of the scan line SL. For example, the first active layers ACT1 may be components of the second transistors T2r, T2g, and T2b, which are switching transistors. A first portion of each of the first active layers ACT1 located in the direction to the data lines DLr, DLg, and DLb may be electrically connected to a corresponding data line among the data lines DLr, DLg, and DLb.

Portions of the second active layer ACT2 may be components of the first transistors T1r, T1g, and T1b, which are driving transistors, may be components of the third transistors T3r, T3g, and T3b, which are initialization-sensing transistors, and may serve as second capacitor electrodes corresponding to the first capacitor electrodes Cst1r, Cst1g, and Cst1b of storage capacitors Cst. This will be described later.

A gate insulating layer 104 may be disposed on the second buffer layer 102 to cover the active layer ACT. The gate insulating layer 104 may include an insulating material. For example, the gate insulating layer 104 may include an inorganic insulating material such as silicon oxide, silicon nitride, silicon oxynitride, or aluminum oxide.

A gate layer GTL shown in FIG. 7 may be disposed on the gate insulating layer 104. For reference, for convenience of illustration, the gate layer GTL is illustrated together with the active layer ACT in FIG. 7.

The gate layer GTL may include the horizontal common voltage line CVLh, the scan line SL, the control line CL, and the horizontal power line PLh each of which substantially extends in the second direction (or x-axis direction), a first common voltage connection line CVCL1 and an initialization-sensing connection line ISCL each of which substantially extends in the first direction (or y-axis direction), and a data connection line DCL, a transistor connection line TCL, a power connection line PLCL, and a shield connection line SCL each of which has an isolated shape. Each of the red subpixel, green subpixel, and blue subpixel may have the data connection line DCL, the transistor connection line TCL, the power connection line PLCL, and the shield connection line SCL. As shown in FIG. 7, the data connection line DCL may include a red data connection line DCLr in the red subpixel, a green data connection line DCLg in the green subpixel, and a blue data connection line DCLb in the blue subpixel. A configuration in the red subpixel will now be described as a representative explanation.

The gate layer GTL may include a metal, an alloy, a conductive metal oxide, or a transparent conductive material. For example, the gate layer GTL may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The gate layer GTL may have a multi-layered structure. For example, the gate layer GTL may have a double-layer structure of Mo/Al or Ti/Al or a three-layered structure of Ti/Al/Ti.

As described above, FIG. 7 shows the gate layer GTL and the active layer ACT together for convenience. Impurities may be added to a portion of the active layer ACT that does not overlap the gate layer GTL. For example, the portion of the active layer ACT that does not overlap the gate layer GTL may be a doped portion. Accordingly, electrical characteristics of the portion of the active layer ACT that does not overlap the gate layer GTL may be different from those of a portion of the active layer ACT that overlaps with the gate layer GTL. For example, resistance of the portion of the active layer ACT that does not overlap the gate layer GTL may be lower than resistance of the portion of the active layer ACT overlapping the gate layer GTL in case that no channels are formed in the overlapping portion. Therefore, for example, in the red subpixel, a portion of the second active layer ACT2 overlapping the first capacitor electrode Cst1r may function as a conductor and be a second capacitor electrode. The portion of the active layer ACT not overlapping the gate layer GTL may be a source region or a drain region, and may also function as a wiring.

The scan line SL may extend substantially in the second direction (or x-axis direction) and may have a protrusion protruding in the first direction (or y-axis direction) crossing the first direction. As described above, the first active layer ACT1 may have a shape extending in the second direction (or x-axis direction) to cross a portion of the scan line SL, and, in particular, may have a shape extending in the second direction (or x-axis direction) so as to cross the protrusion of the scan line SL.

The red data connection line DCLr may be electrically connected to the first portion of the first active layer ACT1 which is disposed below the red data connection line DCLr through a first contact hole CT1 in the red pixel circuit, and may be electrically connected to the red data line DLr which is disposed below the red data connection line DCLr through a second contact hole CT2r in the red pixel circuit. To this end, as shown in FIG. 5, the red data line DLr may include a protrusion protruding in the second direction (or x-axis direction) to correspond to (or overlap) the second contact hole CT2r. This is to ensure that the red data connection line DCLr and the red data line DLr are electrically connected each other. The red data line DLr may be located on one side of the protrusion of the scan line SL. The red data line DLr may be located in the +x direction from the protrusion of the scan line SL. The first portion of the first active layer ACT1 of the red pixel circuit is a portion of the first active layer ACT1 located in a direction to the red data line DLr with respect to the protrusion of the scan line SL. For example, the red data connection line DCLr may electrically connect the second transistor T2r, which is the thin film transistor in the red pixel circuit, to the red data line DLr.

The green data connection line DCLg may be electrically connected to the first portion of the first active layer ACT1 which is disposed below the green data connection line DCLg through a first contact hole CT1 in the green pixel circuit, and may be electrically connected to the green data line DLg which is disposed below the green data connection line DCLg through a second contact hole CT2g in the green pixel circuit. To this end, as shown in FIG. 5, the green data line DLg may include a first protrusion P1 protruding in the second direction (or x-axis direction) to correspond to (or overlap) the second contact hole CT2g. This is to ensure that the green data connection line DCLg and the green data line DLg are electrically connected to each other. Therefore, the first protrusion P1 may be located to correspond to (or overlap) the green pixel circuit. The green data line DLg may be located on one side of the protrusion of the scan line SL. The green data line DLg may be located in the +x direction from the protrusion of the scan line SL. The first portion of the first active layer ACT1 of the green pixel circuit is a portion of the first active layer ACT1 located in a direction to the green data line DLg with respect to the protrusion of the scan line SL. For example, the green data connection line DCLg may electrically connect the second transistor T2g, which is the thin film transistor in the green pixel circuit, to the green data line DLg.

As shown in FIG. 5, the green data line DLg may also have a second protrusion P2 protruding in the second direction (or x-axis direction) at a portion corresponding to the pixel circuit, in addition to the first protrusion P1. The second protrusion P2 will be described later in more detail.

The blue data connection line DCLb may be electrically connected to the first portion of the first active layer ACT1 which is disposed below the blue data connection line DCLb through a first contact hole CT1 in the blue pixel circuit, and may be electrically connected to the blue data line DLb which is disposed below the blue data connection line DCLb through a second contact hole CT2b in the blue pixel circuit. To this end, as shown in FIG. 5, the blue data line DLb may include a protrusion protruding in the second direction (or x-axis direction) to correspond to (or overlap) the second contact hole CT2b. This is to ensure that the blue data connection line DCLb and the blue data line DLb are electrically connected to each other. The blue data line DLb may be located on one side of the protrusion of the scan line SL. The blue data line DLb may be located in the +x direction from the protrusion of the scan line SL. The first portion of the first active layer ACT1 of the blue pixel circuit is a portion of the first active layer ACT1 located in a direction to the blue data line DLb with respect to the protrusion of the scan line SL. For example, the blue data connection line DCLb may electrically connect the second transistor T2b, which is the thin film transistor in the blue pixel circuit, to the blue data line DLb.

The transistor connection line TCL may be electrically connected to the second portion of the first active layer ACT1 through a third contact hole CT3 and may be electrically connected to the first capacitor electrode Cst1r of the bottom metal layer BML through a fourth contact hole CT4. The second portion of the first active layer ACT1 may be a portion of the first active layer ACT1 located in the direction away from the red data line DLr with respect to the protrusion of the scan line SL. A portion of the transistor connection line TCL overlapping the second active layer ACT2 may be a driving gate electrode of the first transistor T1r, which is a driving transistor.

As described above, the portion in the direction to the red data line DLr based on the portion of the second active layer ACT2 overlapping the transistor connection line TCL may serve as a second capacitor electrode. The power connection line PLCL may be electrically connected, through a fifth contact hole CT5, to the portion of the second active layer ACT2 located in the direction away from the red data line DLr based on the portion of the second active layer ACT2 overlapping the transistor connection line TCL. The power connection line PLCL may be electrically connected to the vertical power line PLv which is disposed below the power connection line PLCL, through a sixth contact hole CT6. For reference, the horizontal power line PLh may be electrically connected to the vertical power line PLv which is disposed below the horizontal power line PLh, through a seventh contact hole CT7.

The control line CL may extend substantially in the second direction (or x-axis direction) and may have a protrusion protruding in the first direction (or y-axis direction). The protrusion of the control line CL may serve as an initialization-sensing gate electrode of each of the third transistors T3r, T3g, and T3b, which are initialization-sensing transistors.

The initialization-sensing connection line ISCL may be electrically connected to the second active layer ACT2 which is disposed below the initialization-sensing connection line ISCL through an eighth contact hole CT8, and may be electrically connected to the initialization-sensing line ISL which is disposed below the initialization-sensing connection line ISCL through a ninth contact hole CT9. A portion of the second active layer ACT2 electrically connected to the initialization-sensing connection line ISCL may be a portion of the second active layer ACT2 in the direction to the initialization-sensing connection line ISCL with respect to the protrusion of the control line CL.

The shield connection line SCL may be electrically connected to the second active layer ACT2 through a tenth contact hole CT10, and may be electrically connected to the driving gate electrode shield GSr through an eleventh contact hole CT11.

The first common voltage connection line CVCL1 may be electrically connected to the vertical common voltage line CVLv which is disposed below the first common voltage connection line CVCL1, through a twelfth contact hole CT12. The horizontal common voltage line CVLh may be electrically connected to the vertical common voltage line CVLv which is disposed below the horizontal common voltage line CVLh through a thirteenth contact hole CT13.

A planarization layer 106 may cover the gate layer GTL and may be disposed over the gate layer GTL. The planarization layer 106 may include an organic insulating material. For example, the planarization layer 106 may include photoresist, benzocyclobutene (BCB), polyimide, hexamethyldisiloxane (HMDSO), polymethyl methacrylate (PMMA), polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, or a blend thereof.

A pixel electrode layer PEL as shown in FIG. 8 may be disposed on the planarization layer 106. The pixel electrode layer PEL may include the red pixel electrode PEr, the green pixel electrode PEg, the blue pixel electrode PEb, and a second common voltage connection line CVCL2. The pixel electrode layer PEL may be a (semi) light-transmissive electrode layer or a reflective electrode layer. For example, the pixel electrode layer PEL may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer disposed over the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode layer PEL may have a three-layered structure of ITO/Ag/ITO.

The red pixel electrode PEr may be electrically connected to the second active layer ACT2 of the red pixel circuit through a contact hole CTr defined in the planarization layer 106, etc., the green pixel electrode PEg may be electrically connected to the second active layer ACT2 of the green pixel circuit through a contact hole CTg defined in the planarization layer 106, etc., and the blue pixel electrode PEb may be electrically connected to the second active layer ACT2 of the blue pixel circuit through a contact hole CTb defined in the planarization layer 106, etc. Similarly, the second common voltage connection line CVCL2 may be electrically connected to the first common voltage connection line CVCL1 which is disposed below the second common voltage connection line CVCL2 through a contact hole CTCE defined in the planarization layer 106, etc.

A pixel defining layer 107 may be disposed over the planarization layer 106. The pixel defining layer 107 may have openings to expose respective central portions of the red pixel electrode PEr, the green pixel electrode PEg, and the blue pixel electrode PEb, and may cover respective edges of the red pixel electrode PEr, the green pixel electrode PEg, and the blue pixel electrode PEb. Accordingly, the pixel defining layer 107 may prevent an arc or the like from occurring at the respective edges of the red pixel electrode PEr, the green pixel electrode PEg, and the blue pixel electrode PEb by increasing a distance between the edge of each of the red pixel electrode PEr, the green pixel electrode PEg, and the blue pixel electrode PEb and a common electrode CE over the red pixel electrode PEr, the green pixel electrode PEg, and the blue pixel electrode PEb. The pixel defining layer 107 may expose at least a portion of the second common voltage connection line CVCL2 so that the common electrode CE contacts the second common voltage connection line CVCL2 to be electrically connected to the common voltage line CVL including the vertical common voltage line CVLv and the horizontal common voltage line CVLh through the first common voltage connection line CVCL1 and the second common voltage connection line CVCL2. The pixel defining layer 107 may be formed of at least one organic insulating material from among polyimide, polyamide, acryl resin, benzocyclobutene, and a phenolic resin, by using a method such as spin coating.

The common electrode CE may be a light-transmissive electrode or a reflective electrode. For example, the common electrode CE may be a transparent or semi-transparent electrode, and may include a metal thin film having a small work function, including Li, Ca, LiF, Al, Ag, Mg, or a combination thereof. The common electrode CE may further include a transparent conductive oxide (TCO) layer of, for example, ITO, IZO, ZnO, or In₂O₃, disposed over the metal thin film. The common electrode CE may be integrally formed as a single body over the entire surface of the display area DA and disposed over multiple pixel electrodes.

An intermediate layer may be disposed between the pixel electrodes and the common electrode CE, and at least a portion of the intermediate layer may be located within openings defined by the pixel defining layer 107. An emission region of the organic light-emitting diode OLED may be defined by the openings. The intermediate layer may include an emission layer. The emission layer may include an organic material including a fluorescent or phosphorescent material that emits red, green, blue, or white light. The emission layer may include a low molecular organic material or a high molecular organic material, and one or more functional layers, such as a hole transport layer (HTL), a hole injection layer (HIL), an electron transport layer (ETL), and an electron injection layer (EIL), may be further arranged below and above the emission layer.

The emission layer may have a shape patterned in correspondence with each pixel electrode. Various modifications may be made to layers of the intermediate layer other than the emission layer. For example, a layer other than the emission layer included in the intermediate layer may be integrally formed as a single body over multiple pixel electrodes. If the display panel 10 includes the filter panel 10b as described above, the emission layer may also be formed as a single body throughout multiple pixel electrodes.

An encapsulation layer for protecting the organic light-emitting diode OLED may be disposed over the common electrode CE, and a touch screen layer, etc. may be disposed over the encapsulation layer, if necessary. The encapsulating layer may include a stack structure of a first inorganic encapsulating layer, an organic encapsulating layer, and a second inorganic encapsulating layer. A detailed explanation about the encapsulation layer will be omitted for convenience.

The portion indicated by the dashed-dotted line in FIGS. 4 through 8 may appear repeatedly along the second direction (or x-axis direction) within the display area DA of the display panel 10. Likewise, the portion indicated by the dashed-dotted line in FIGS. 4 through 8 may appear repeatedly along the first direction (or y-axis direction) within the display area DA of the display panel 10. In another embodiment, in the first direction (or y-axis direction), for example, the portion indicated by the dashed-dotted line in FIGS. 4 through 8 may appear in odd-numbered rows and the portion indicated by the dashed-dotted line in FIGS. 4 through 8, except the horizontal common voltage line CVLh and the horizontal power line PLh, may appear in even-numbered rows, or vice versa. In case that n is an integer greater than or equal to 0, in the first direction (or y-axis direction), a (2n+1)^{th} pixel and a (2n+2)^{th} pixel may share one horizontal common voltage line CVLh , and the (2n+2)^{th} pixel and a (2n+3)^{th} pixel may share one horizontal power line PLh.

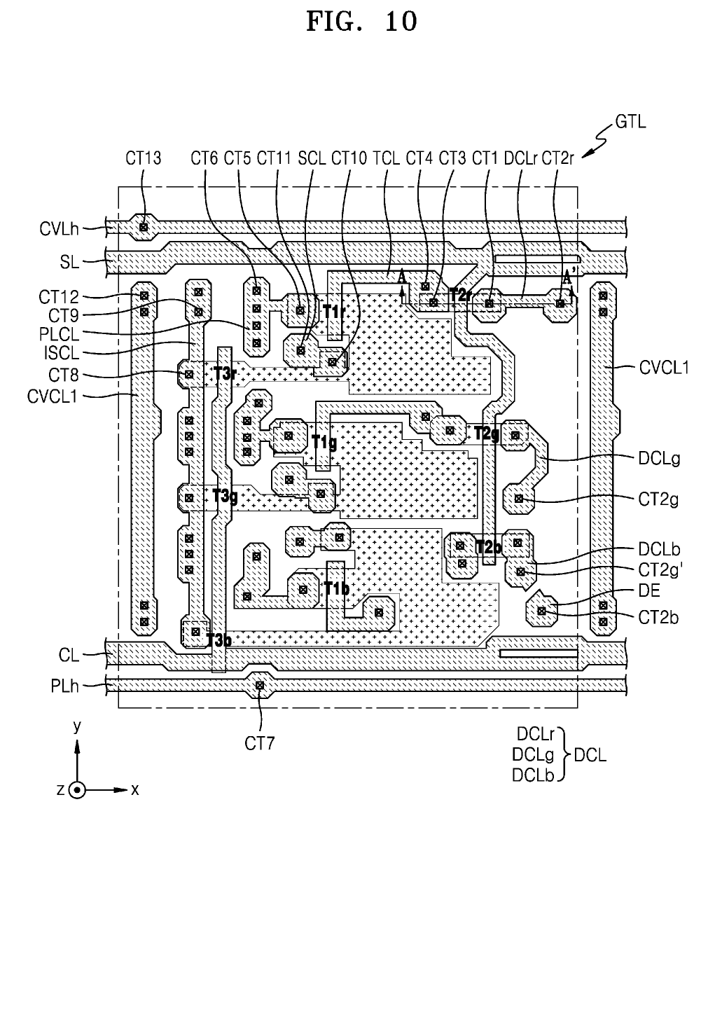

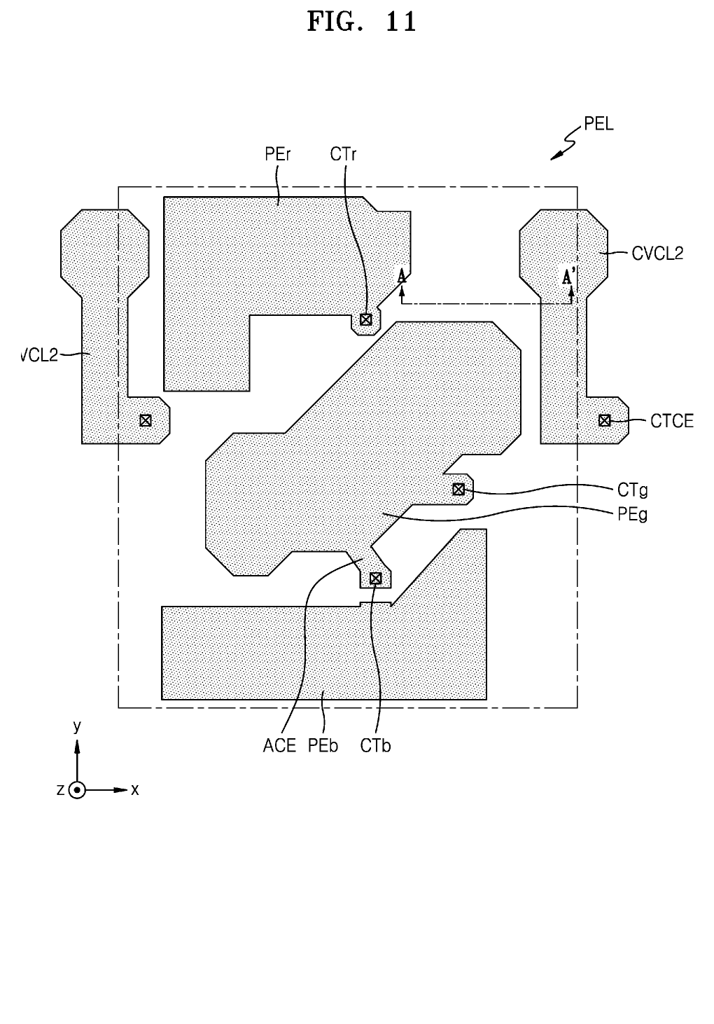

FIGS. 10 and 11 are schematic layout diagrams illustrating some layers of components such as thin film transistors and storage capacitors of the display panel 10 according to an embodiment. FIGS. 10 and 11 are schematic layout diagrams illustrating the gate layer GTL and the pixel electrode layer PEL of the display panel 10. For the layers of the display panel 10 other than the gate layer GTL and the pixel electrode layer PEL, the previous description with reference to FIGS. 4 through 9 may be applied.

The display panel 10 and the electronic apparatus including the display panel 10 according to the embodiment are cases where a defect in the pixel circuit of the green subpixel is discovered during the manufacturing process and the defect is repaired during the manufacturing process so as to minimize deterioration in the quality of the displayed image.

As described above, in case that the display panel 10 and the electronic apparatus including the display panel 10 display the white image, the proportion of blue light in the white light may be about 10%, the proportion of red light in the white light may be about 20%, and the proportion of green light in the white light may be about 70%. Therefore, if a defect occurs in the pixel circuit of the green subpixel and thus the green subpixel does not emit green light, a user may easily recognize the defect. Therefore, if a defect in the pixel circuit of the green subpixel is discovered during the manufacturing process, it is desirable to repair the defect during the manufacturing process.

To this end, the pixel circuit of the blue subpixel may be used instead of the pixel circuit of the green subpixel so that green light is emitted by the green subpixel. For example, no blue light may be emitted from the blue subpixel. As described above, because the proportion of blue light in the white light is about 10%, the user may not be aware that blue light is not emitted from the blue subpixel. In the display panel 10 and the electronic apparatus including the display panel 10, only the pixels where a defect has occurred may have a structure as described below, and the pixels where a defect has not occurred may have a structure as described above with reference to FIGS. 4 through 9.

The data connection line DCL in the repaired pixel will be described with reference to FIG. 10.

The red data connection line DCLr may be electrically connected to the first portion of the first active layer ACT1 which is disposed below the red data connection line DCLr through the first contact hole CT1 in the red pixel circuit, and may be electrically connected to the red data line DLr which is disposed below the red data connection line DCLr through the second contact hole CT2r in the red pixel circuit. The red data line DLr may be located on one side of the protrusion of the scan line SL. The red data line DLr may be located in the +x direction from the protrusion of the scan line SL. The first portion of the first active layer ACT1 of the red pixel circuit may be the portion of the first active layer ACT1 located in the direction to the red data line DLr with respect to the protrusion of the scan line SL. For example, the red data connection line DCLr may electrically connect the second transistor T2r, which is the thin film transistor in the red pixel circuit, to the red data line DLr.

The green data connection line DCLg may be electrically connected to the first portion of the first active layer ACT1 which is disposed below the green data connection line DCLg through the first contact hole CT1 in the green pixel circuit, and may be electrically connected to the green data line DLg which is disposed below the green data connection line DCLg through the second contact hole CT2g in the green pixel circuit. The green data line DLg may be located on one side of the protrusion of the scan line SL. The green data line DLg may be located in the +x direction from the protrusion of the scan line SL. The first portion of the first active layer ACT1 of the green pixel circuit is the portion of the first active layer ACT1 located in the direction to the green data line DLg with respect to the protrusion of the scan line SL. For example, the green data connection line DCLg may electrically connect the second transistor T2g, which is the thin film transistor in the green pixel circuit, to the green data line DLg. However, as described above, the green pixel circuit of the green subpixel may not work due to a defect.

The blue data connection line DCLb may be electrically connected to the first portion of the first active layer ACT1 which is disposed below the blue data connection line DCLb through the first contact hole CT1 in the blue pixel circuit. However, the blue data connection line DCLb is not electrically connected to the blue data line DLb, but may be electrically connected to the green data line DLg which is disposed below the blue data connection line DCLb through an additional contact hole CT2g'. The first portion of the first active layer ACT1 of the blue pixel circuit is the portion of the first active layer ACT1 located in the direction to the blue data line DLb with respect to the protrusion of the scan line SL. For example, the blue data connection line DCLb may electrically connect the second transistor T2b, which is the thin film transistor included in the blue pixel circuit, to the green data line DLg, not the blue data line DLb. Accordingly, the blue pixel circuit may receive an electrical signal from the green data line DLg.

As described above with reference to FIG. 5, the green data line DLg may have the first protrusion P1 protruding in the second direction (or x-axis direction) to correspond to (or overlap) the second contact hole CT2g and may also have the second protrusion P2 protruding in the second direction (or x-axis direction), at the portion corresponding to the pixel circuit. The blue data connection line DCLb may not be electrically connected to the blue data line DLb, but may be electrically connected to the green data line DLg which is disposed below the blue data connection line DCLb through the additional contact hole CT2g', and the second protrusion P2 of the green data line DLg may correspond to (or overlap) this additional contact hole CT2g'. This is to ensure that the blue data connection line DCLb and the green data line DLg are electrically connected each other. To this end, the second protrusion P2 may be located to correspond to (or overlap) the blue pixel circuit.

For example, the green data line DLg may have multiple protrusions that protrude in the direction crossing the first direction (or y-axis direction) at the portion corresponding to the pixel circuit, and one of multiple protrusions may be located to correspond to (or overlap) the green pixel circuit, and another one of multiple protrusions may be located to correspond to (or overlap) the blue pixel circuit.

As shown in FIG. 10, a dummy electrode DE may be present in the repaired pixel. The dummy electrode DE may be in the blue pixel circuit. The dummy electrode DE may be disposed on the gate insulating layer 104 as the blue data connection line DCLb, has an isolated shape in a plan view, and may be electrically connected to the blue data line DLb which is disposed below the dummy electrode DE through the second contact hole CT2b. The dummy electrode DE may be located over the blue data line DLb so as to overlap the blue data line DLb in a plan view.

As illustrated in FIG. 11, the red pixel electrode PEr may be electrically connected to the second active layer ACT2 of the red pixel circuit through the contact hole CTr defined in the planarization layer 106, etc., and the green pixel electrode PEg may be electrically connected to the second active layer ACT2 of the green pixel circuit through the contact hole CTg defined in the planarization layer 106, etc. In contrast, the blue pixel electrode PEb may have an isolated shape in a plan view and may not be electrically connected to the blue pixel circuit. Instead, the green pixel electrode PEg may be electrically connected to the blue pixel circuit through an additional connecting electrode ACE. The additional connecting electrode ACE may be disposed on the planarization layer 106 as the blue pixel electrode PEb. The additional connecting electrode ACE may be electrically connected to the second active layer ACT2 of the blue pixel circuit through the contact hole CTb defined in the planarization layer 106, etc. By electrically connecting the additional connecting electrode ACE to the green pixel electrode PEg, the green pixel electrode PEg may be electrically connected to the green data line DLg through the blue pixel circuit.

In the repaired pixel, the green pixel electrode PEg may be electrically connected to both the green pixel circuit and the blue pixel circuit, and both the green pixel circuit and the blue pixel circuit may be electrically connected to the green data line DLg. Accordingly, even if a defect occurs in the green pixel circuit and the green pixel circuit may not transmit a signal corresponding to an electrical signal from the green data line DLg to the green pixel electrode PEg, the green subpixel may emit green light normally through the blue pixel circuit. Through this configuration, it is possible to prevent or minimize the possibility that a view may recognize the occurrence of defect while using the display panel 10 and the electronic apparatus including the display panel 10.

If necessary, in the green subpixel, a portion of the green data connection line DCLg, which is disposed between the portion of the green data connection line DCLg corresponding to the first contact hole CT1 and the portion of the green data connection line DCLg corresponding to the second contact hole CT2g may be cut so that the green pixel electrode PEg may be electrically connected only to the blue pixel circuit.

A repair process is described to repair the green pixel circuit as shown in FIGS. 10 and 11, in case that a defect occurs in the green pixel circuit during the manufacturing process.

Firstly, a display panel 10 having the same structure as described above with reference to FIGS. 4 through 9 is manufactured. As shown in FIG. 8, after forming the pixel electrode layer PEL and before forming the pixel defining layer 107, optical inspection may be performed to check if there is a defect in the pixel circuit. If a defect in the green pixel circuit in the green subpixel is identified during such an inspection process, a repair procedure for that subpixel may be initiated.

For the repair, the blue pixel circuit is electrically connected to the green data line DLg, and the blue pixel circuit is electrically isolated from the blue data line DLb.

To electrically connect the blue pixel circuit to the green data line DLg, a laser beam may be irradiated onto the gate layer GTL shown in FIG. 7. The laser beam may be irradiated onto a portion of the blue data connection line DCLb. The portion may be over the green data line DLg. Through this process, an additional contact hole CT2g' is defined (or formed) in the insulating layers such as the second buffer layer 102 and the gate insulating layer 104 between the blue data connection line DCLb and the green data line DLg so that the portion of the blue data connection line DCLb over the green data line DLg may be electrically connected to the green data line DLg. During this process, the portion of the blue data connection line DCLb over the green data line DLg may be temporarily melt and then solidify again.

In order to electrically insulate the blue pixel circuit from the blue data line DLb, a laser beam may be irradiated onto a portion of the blue data connection line DCLb. The portion of the blue data connection line DCLb may be disposed between the portion of the blue data connection line DCLb corresponding to the additional contact hole CT2g' and the portion of the blue data connection line DCLb corresponding to the second contact hole CT2b such that the blue data connection line DCLb may be separated into two portions. Accordingly, as shown in FIG. 10, the blue data connection line DCLb may be electrically connected to the green data line DLg through the additional contact hole CT2g', and the dummy electrode DE which has the isolated shape and is spaced apart from the blue data connection line DCLb may be electrically connected to the blue data line DLb through the second contact hole CT2b.

For convenience, irradiation order of the laser beams may be changed. For example, a laser beam may be irradiated onto the portion of the blue data connection line DCLb, which is disposed between the portion of the blue data connection line DCLb over the green data line DLg and the portion of the blue data connection line DCLb corresponding to the second contact hole CT2b, to separate the blue data connection line DCLb into the two portions, and then a laser beam may be irradiated onto the portion of the blue data connection line DCLb over the green data line DLg to electrically connect the blue data connection line DCLb to the green data line DLg.

For reference, in case that irradiating the laser beam onto the portion of the blue data connection line DCLb, which is disposed between the portion of the blue data connection line DCLb over the green data line DLg and the portion of the blue data connection line DCLb corresponding to the second contact hole CT2b, to separate the blue data connection line DCLb into the two portions, there may be no conductive layer over and which is disposed below the portion of the blue data connection line DCLb onto which the laser beam is irradiated. Accordingly, the portion of the blue data connection line DCLb over the green data line DLg and the portion of the blue data connection line DCLb corresponding to the second contact hole CT2b may be effectively electrically insulated from each other.

If necessary, in the green subpixel, a laser beam may be irradiated onto a portion of the green data connection line DCLg, which is disposed between a portion of the green data connection line DCLg corresponding to the first contact hole CT1 and a portion of the green data connection line DCLg corresponding to the second contact hole CT2g such that the green data connection line DCLg is separated into two portions. This may electrically isolate the pixel circuit of the green subpixel from the green data line DLg. This may apply to the embodiments and variations thereof described below.

The blue pixel electrode PEb shown in FIG. 8 may be separated into two portions by irradiating a laser beam onto the blue pixel electrode PEb. By irradiating a laser beam onto a portion of the blue pixel electrode PEb, which is disposed between a portion of the blue pixel electrode PEb corresponding to the contact hole CTb defined in the planarization layer 106 and a portion of the blue pixel electrode PEb to be exposed by the opening of the pixel defining layer 107, the blue pixel electrode PEb may be separated into two portions. Because the planarization layer 106 under the blue pixel electrode PEb is thicker than other insulating layers under the planarization layer 106, the portion of the blue pixel electrode PEb onto which the laser beam is irradiated may be prevented from being electrically connected to the second active layer ACT2 under the blue pixel electrode PEb during this process.

Thereafter, by electrically connecting the portion of the blue pixel electrode PEb corresponding to the contact hole CTb defined in the planarization layer 106 to the green pixel electrode PEg, the green pixel electrode PEg may be electrically connected to the blue pixel circuit through the contact hole CTb, as shown in FIG. 11. Electrically connecting the portion of the blue pixel electrode PEb corresponding to the contact hole CTb defined in the planarization layer 106 to the green pixel electrode PEg may be performed, for example, by dotting conductive ink using an inkjet printing method. Conductive ink may include a conductive material, such as copper nanoparticles, silver nanoparticles, or graphene particles.

Accordingly, the blue pixel electrode PEb may have an isolated shape in a plan view and may not be electrically connected to the blue pixel circuit. Instead, the green pixel electrode PEg may be electrically connected to the blue pixel circuit through the additional connecting electrode ACE formed by inkjet printing or the like using conductive ink.

The order may be changed. For example, by dotting conductive ink using an inkjet printing method to form the additional connection electrode ACE, the portion of the blue pixel electrode PEb corresponding to the contact hole CTb defined in the planarization layer 106 may be electrically connected to the green pixel electrode PEg. Then, by irradiating a laser beam onto the portion of the blue pixel electrode PEb, which is disposed between the portion of the blue pixel electrode PEb corresponding to the contact hole CTb defined in the planarization layer 106 and the portion of the blue pixel electrode PEb exposed by the opening of the pixel defining layer 107, the blue pixel electrode PEb may be separated into the two portions.

In order to facilitate electrical connection between the green pixel electrode PEg and the blue pixel circuit using the inkjet printing method or the like, the green pixel electrode PEg may be disposed adjacent to the blue pixel electrode PEb within a pixel. As shown in FIG. 8, FIG. 11, etc., in a plan view, the green pixel electrode PEg may be disposed relatively closer to the blue pixel electrode PEb than to the red pixel electrode PEr. For example, in a plan view, the center of the green pixel electrode PEg may be disposed between the center of the red pixel electrode PEr and the center of the blue pixel electrode PEb. In the pixel repaired in the manner described above, the additional connection electrode ACE may be disposed between the green pixel electrode PEg and the blue pixel electrode PEb.

For reference, after electrically connecting the blue data connection line DCLb to the green data line DLg as shown in FIG. 10, the blue pixel electrode PEb may be separated into two portions as shown in FIG. 11. In another embodiment, after separating the blue pixel electrode PEb into two portions as shown in FIG. 11, the blue data connection line DCLb may be electrically connected to the green data line DLg as shown in FIG. 10. In other embodiments, various modifications may be possible. For example, after separating the blue pixel electrode PEb into two portions as shown in FIG. 11, the blue pixel electrode PEb may be separated into two portions as shown in FIG. 10 such that the dummy electrode DE is formed and the blue data connection line DCLb is electrically connected to the green data line DLg as shown in FIG. 10, and then the additional connection electrode ACE may be formed as shown in FIG. 11 using the inkjet printing method or the like.

After performing the repair in this manner, the pixel defining layer 107 may be formed to expose the central portion of each of the red pixel electrode PEr, the green pixel electrode PEg, and the blue pixel electrode PEb and to cover the edge of each of the red pixel electrode PEr, the green pixel electrode PEg, and the blue pixel electrode PEb. Then, the intermediate layer including the emission layer may be formed and the common electrode CE may be formed such that the display panel 10 is manufactured.

In order to electrically connect the blue pixel circuit to the green data line DLg during the repair process, the laser beam may be irradiated onto the portion of the blue data connection line DCLb over the green data line DLg as described above. To this end, as shown in FIGS. 4 and 5, the green data line DLg among the red data line DLr, the green data line DLg, and the blue data line DLb may be made closest to the pixel circuit. For example, the blue data connection line DCLb of the blue pixel circuit has a shape extended over the green data line DLg.

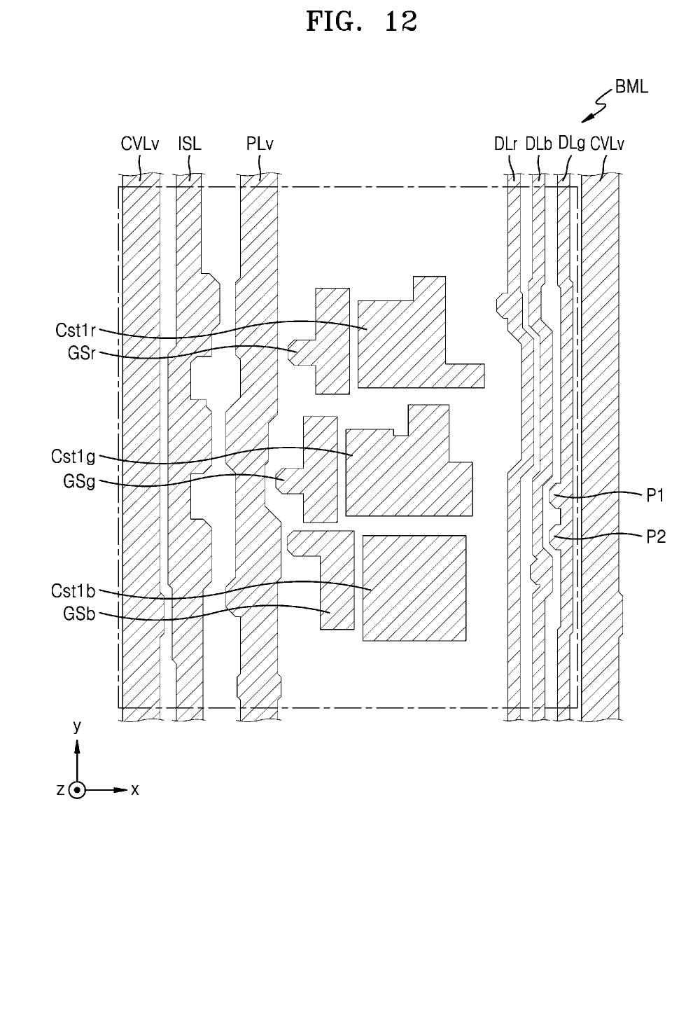

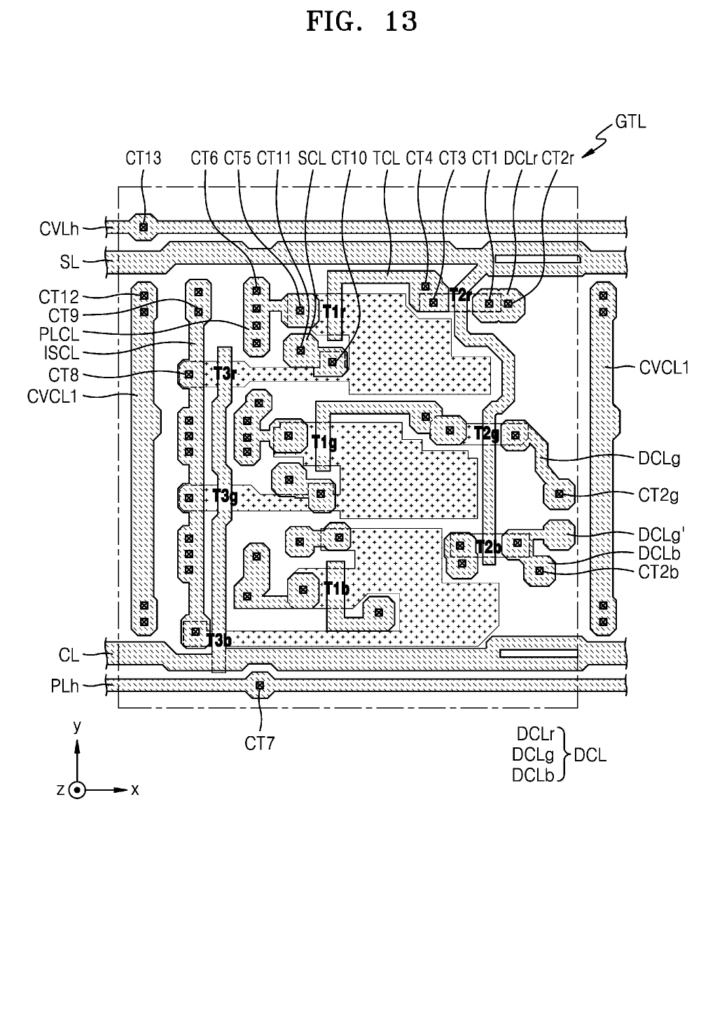

However, embodiments are not limited thereto. For example, as shown in FIGS. 12 and 13, which are schematic layout diagrams illustrating some layers of the components such as the thin film transistors and the storage capacitors of the display panel 10 according to an embodiment, the green data line DLg among the red data line DLr, the green data line DLg, and the blue data line DLb may be located farthest from the pixel circuit to which the red data line DLr, the green data line DLg, and the blue data line DLb are electrically connected. This also ensures that the green data line DLg is not between the red data line DLr and the blue data line DLb. Through this, the display panel 10 and the electronic apparatus including the display panel 10, in which a high-quality image is displayed, may be implemented.

The red pixel circuit may include the red data connection line DCLr as described above. The green pixel circuit may include the green data connection line DCLg as described above.

The blue pixel circuit may include the blue data connection line DCLb as described above, and may further include a dummy connection line DCLg'. The dummy connection line DCLg' may be electrically connected to the first portion of the first active layer ACT1 which is disposed below the dummy connection line DCLg' through the first contact hole CT1 of the blue pixel circuit, similar to the blue data connection line DCLb. For example, the dummy connection line DCLg' and the blue data connection line DCLb may be simultaneously formed from the same material on the same layer, and further, the dummy connection line DCLg' and the blue data connection line DCLb may be integrally formed as a single body. For example, the dummy connection line DCLg' electrically connected to the thin film transistor of the blue pixel circuit may be extended over the green data line DLg.

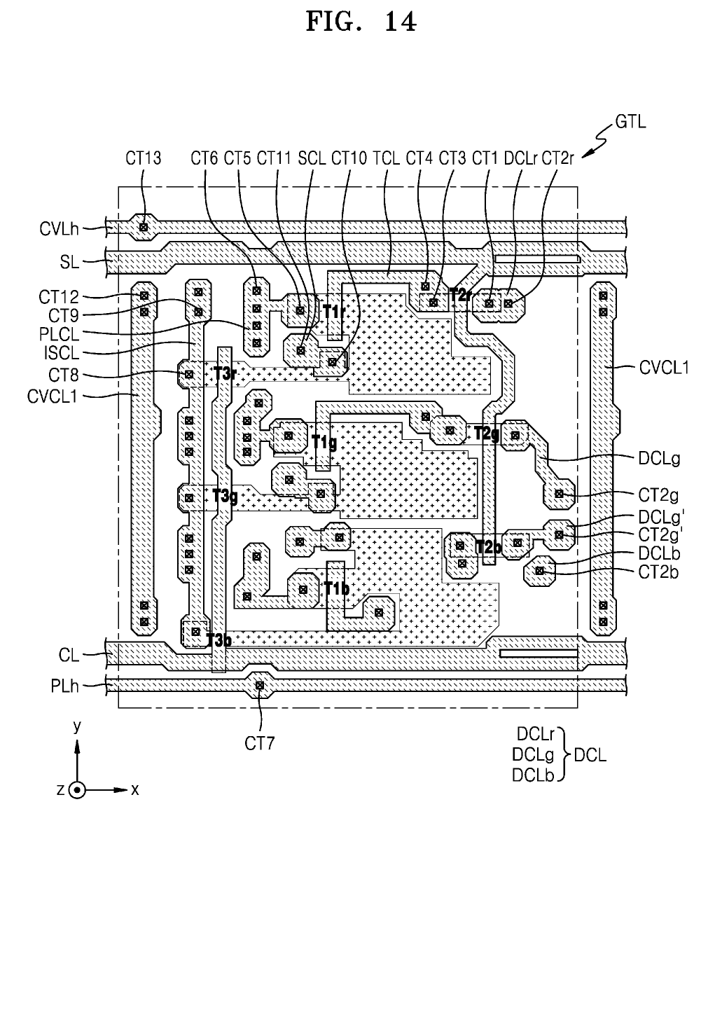

FIG. 14 is a schematic layout diagram illustrating some layers of the components such as the thin film transistors and the storage capacitors of the display panel 10 according to an embodiment. FIG. 14 is a schematic layout diagram illustrating the gate layer GTL included in the display panel 10. The description above with reference to FIG. 11 may be applied to the pixel electrode layer PEL of the display panel 10, and the description above with reference to FIGS. 4 through 9 may be applied to the layers of the display panel 10 other than the gate layer GTL and the pixel electrode layer PEL.

The display panel 10 and the electronic apparatus including the display panel 10 according to the embodiment are cases where a defect in the pixel circuit of the green subpixel is discovered during the manufacturing process and the defect is repaired during the manufacturing process so as to minimize deterioration in the quality of the displayed image.

As described above, in case that the display panel 10 and the electronic apparatus including the display panel 10 display the white image, the proportion of blue light in the white light may be about 10%, the proportion of red light in the white light may be about 20%, and the proportion of green light in the white light may be about 70%. Therefore, if a defect occurs in the pixel circuit of the green subpixel and thus the green subpixel does not emit green light, a user may easily recognize the defect. Therefore, if a defect in the pixel circuit of the green subpixel is discovered during the manufacturing process, it is desirable to repair the defect during the manufacturing process.

To this end, the pixel circuit of the blue subpixel may be used instead of the pixel circuit of the green subpixel so that green light is emitted in the green subpixel. For example, no blue light is emitted from the blue subpixel. As described above, because the proportion of blue light in the white light is about 10%, the user may not be aware that blue light is not emitted from the blue subpixel. In the display panel 10 and the electronic apparatus including the display panel 10, only the pixels where a defect has occurred may have a structure as described below, and the pixels where a defect has not occurred may have a structure as described above with reference to FIGS. 4 through 9.

The data connection line DCL in the repaired pixel will be described with reference to FIG. 14.

The red data connection line DCLr may electrically connect the second transistor T2r, which is the thin film transistor of the red pixel circuit, to the red data line DLr, as described above. The green data connection line DCLg may electrically connect the second transistor T2g, which is the thin film transistor of the green pixel circuit, to the green data line DLg, as described above. However, as described above, the green pixel circuit of the green subpixel may not work due to a defect.

The blue data connection line DCLb may be electrically isolated from the blue pixel circuit. The blue data connection line DCLb may be electrically connected to the blue data line DLb through the second contact hole CT2b as shown in FIG. 14, however, the blue data connection line DCLb may have an isolated shape in a plan view so that the blue data connection line DCLb may be electrically insulated from the blue pixel circuit.

The dummy connection line DCLg' may be electrically connected to the first portion of the first active layer ACT1 under the dummy connection line DCLg' through the first contact hole CT1 of the blue pixel circuit. The dummy connection line DCLg' may not be electrically connected to the blue data line DLb, but may be electrically connected to the green data line DLg under the dummy connection line DCLg' through the additional contact hole CT2g'. The first portion of the first active layer ACT1 of the blue pixel circuit is the portion of the first active layer ACT1 located in the direction to the blue data line DLb with respect to the protrusion of the scan line SL. For example, the dummy connection line DCLg' may electrically connect the second transistor T2b, which is the thin film transistor of the blue pixel circuit, to the green data line DLg, not the blue data line DLb. Accordingly, the blue pixel circuit may receive an electrical signal from the green data line DLg.

The display panel 10 and the electronic apparatus including the display panel 10 according to the embodiment may include the pixel electrode layer PEL as shown in FIG. 11. As shown in FIG. 11, the red pixel electrode PEr may be electrically connected to the second active layer ACT2 of the red pixel circuit through the contact hole CTr defined in the planarization layer 106, etc., and the green pixel electrode PEg may be electrically connected to the second active layer ACT2 of the green pixel circuit through the contact hole CTg defined in the planarization layer 106, etc. In contrast, the blue pixel electrode PEb may have an isolated shape in a plan view and may not be electrically connected to the blue pixel circuit. Instead, the green pixel electrode PEg may be electrically connected to the blue pixel circuit through the additional connecting electrode ACE. The additional connecting electrode ACE may be on the planarization layer 106 as the blue pixel electrode PEb. The additional connecting electrode ACE may be electrically connected to the second active layer ACT2 of the blue pixel circuit through the contact hole CTb defined in the planarization layer 106, etc. By electrically connecting the additional connecting electrode ACE to the green pixel electrode PEg, the green pixel electrode PEg may be electrically connected to the green data line DLg through the blue pixel circuit.

In the repaired pixel, the green pixel electrode PEg may be electrically connected to both the green pixel circuit and the blue pixel circuit, and both the green pixel circuit and the blue pixel circuit may be electrically connected to the green data line DLg. Accordingly, even if a defect occurs in the green pixel circuit and the green pixel circuit may not transmit a signal corresponding to an electrical signal from the green data line DLg to the green pixel electrode PEg, the green subpixel may emit green light normally through the blue pixel circuit. Through this configuration, it is possible to prevent or minimize the possibility that a view may recognize the occurrence of defect while using the display panel 10 and the electronic apparatus including the display panel 10.

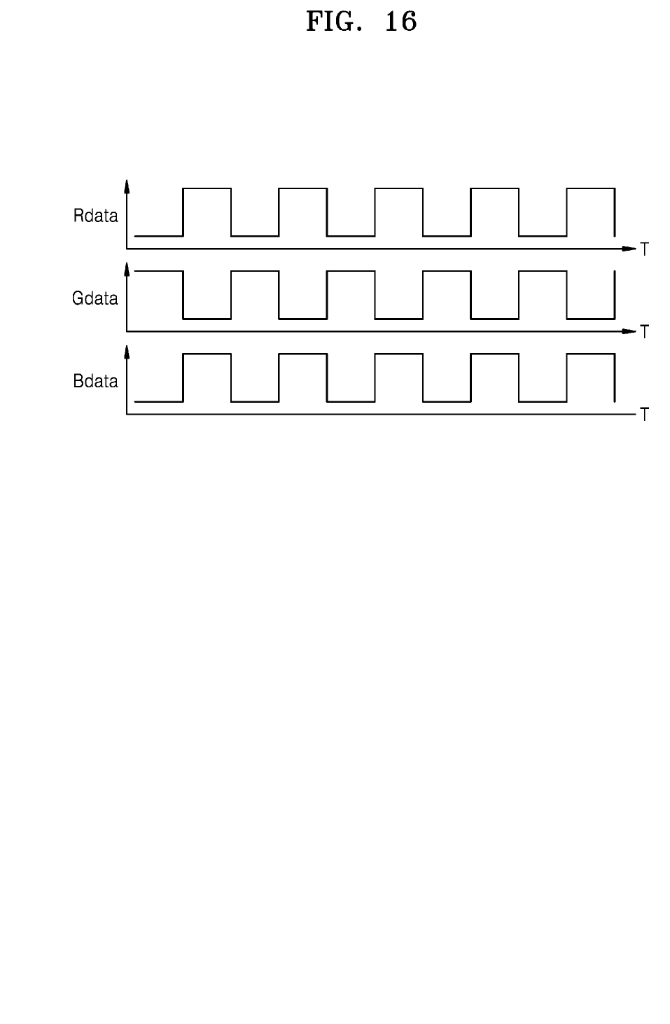

A repair process is described to repair the green pixel circuit as shown in FIGS. 16 and 11, in case that a defect occurs in the green pixel circuit during the manufacturing process.

Firstly, a display panel 10 having the same structure as described above with reference to FIG. 13 is manufactured. After forming the gate layer GTL as shown in FIG. 13, the pixel electrode layer PEL as shown in FIG. 8 is also formed over the gate layer GTL. After forming the pixel electrode layer PEL and before forming the pixel defining layer 107, optical inspection may be performed to check if there is a defect in the pixel circuit. in case that a defect in the green pixel circuit in the green subpixel is identified during such an inspection process, a repair procedure for that subpixel may be initiated.

For the repair, the blue pixel circuit is electrically connected to the green data line DLg, and the blue pixel circuit is electrically isolated from the blue data line DLb.

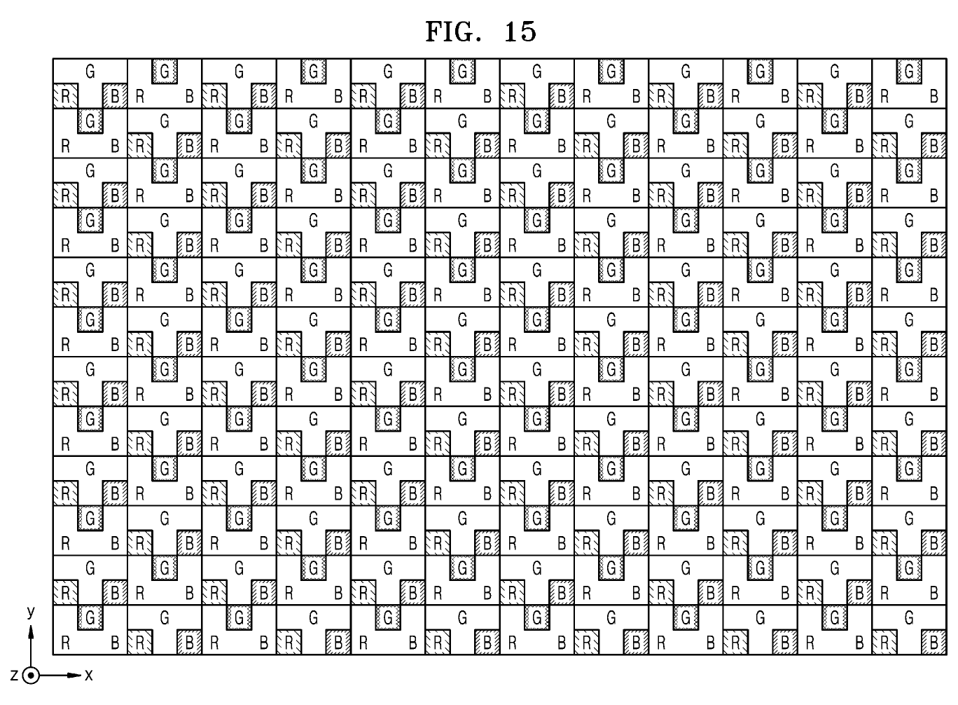

To electrically connect the blue pixel circuit to the green data line DLg, a laser beam may be irradiated onto the gate layer GTL shown in FIG. 15. A laser beam may be irradiated onto a portion of the dummy connection line DCLg'. The portion may be over the green data line DLg. Through this, the additional contact hole CT2g' may be defined (or formed) in the insulating layers such as the second buffer layer 102 and the gate insulating layer 104 between the dummy connection line DCLg' and the green data line DLg so that the portion of the dummy connection line DCLg' over the green data line DLg may be electrically connected to the green data line DLg. During this process, the portion of the dummy connection line DCLg' over the green data line DLg may be temporarily melt and then solidify again.

In order to electrically insulate the blue pixel circuit from the blue data line DLb, a laser beam may be irradiated onto a portion of the blue data connection line DCLb. The portion of the blue data connection line DCLb may be disposed between the portion of the blue data connection line DCLb corresponding to the first contact hole CT1 and the portion of the blue data connection line DCLb corresponding to the second contact hole CT2b such that the blue data connection line DCLb may be separated into two portions. As described above, because the dummy connection line DCLg' and the blue data connection line DCLb were initially integrally formed as a single body, the portion of the blue data connection line DCLb corresponding to the first contact hole CT1 may be regarded as a portion of the dummy connection line DCLg'. Accordingly, as illustrated in FIG. 14, the dummy connection line DCLg' may be electrically connected to the green data line DLg through the additional contact hole CT2g'. The blue data connection line DCLb may be electrically connected to the blue data line DLb through the second contact hole CT2b, but may have an isolated shape in a plan view. As described above, because the dummy connection line DCLg' and the blue data connection line DCLb were initially integrally formed as a single body, after repair, the dummy connection line DCLg' and the blue data connection line DCLb may be on the same layer.

For convenience, irradiation order of the laser beams may be changed. For example, a laser beam may be irradiated onto the portion of the blue data connection line DCLb, which is disposed between the portion of the blue data connection line DCLb corresponding to the first contact hole CT1 and the portion of the blue data connection line DCLb corresponding to the second contact hole CT2b, to separate the blue data connection line DCLb into the two portions, and then a laser beam may be irradiated onto the portion of the dummy connection line DCLg' over the green data line DLg to electrically connect the dummy connection line DCLg' to the green data line DLg.

For reference, in case that irradiating the laser beam onto the portion of the blue data connection line DCLb, which is disposed between the portion of the blue data connection line DCLb corresponding to the first contact hole CT1 and the portion of the blue data connection line DCLb corresponding to the second contact hole CT2b, to separate the blue data connection line DCLb into the two portions, there may be no conductive layer over and below the portion of the blue data connection line DCLb onto which the laser beam is irradiated. Accordingly, the portion of the blue data connection line DCLb corresponding to the first contact hole CT1 and the portion of the blue data connection line DCLb corresponding to the second contact hole CT2b may be effectively electrically insulated from each other.

As described above, by irradiating the laser beam onto the blue pixel electrode PEb as shown in FIG. 8, the blue pixel electrode PEb may be separated into the two portions as shown in FIG. 11. Then, by electrically connecting the portion of the blue pixel electrode PEb corresponding to the contact hole CTb defined in the planarization layer 106 to the green pixel electrode PEg, the green pixel electrode PEg may be electrically connected to the blue pixel circuit through the contact hole CTb, as shown in FIG. 11. Electrically connecting the portion of the blue pixel electrode PEb corresponding to the contact hole CTb defined in the planarization layer 106, etc. to the green pixel electrode PEg may be accomplished, for example, by dotting conductive ink using the inkjet printing method. Conductive ink may include a conductive material, such as copper nanoparticles, silver nanoparticles, or graphene particles.

Accordingly, the blue pixel electrode PEb may have an isolated shape in a plan view and is not electrically connected to the blue pixel circuit. Instead, the green pixel electrode PEg may be electrically connected to the blue pixel circuit through the additional connecting electrode ACE formed by inkjet printing or the like using conductive ink.

In another embodiment, the order may be changed. For example, by dotting conductive ink using the inkjet printing method to form the additional connection electrode ACE, the portion of the blue pixel electrode PEb corresponding to the contact hole CTb defined in the planarization layer 106 may be electrically connected to the green pixel electrode PEg. Then, by irradiating a laser beam onto the portion of the blue pixel electrode PEb, which is disposed between the portion of the blue pixel electrode PEb corresponding to the contact hole CTb defined in the planarization layer 106 and the portion of the blue pixel electrode PEb exposed by the opening of the pixel defining layer 107, the blue pixel electrode PEb may be separated into the two portions.

In order to facilitate electrical connection between the green pixel electrode PEg and the blue pixel circuit using the inkjet printing method or the like, the green pixel electrode PEg and the blue pixel electrode PEb may be located adjacent to each other within a pixel. As shown in FIG. 8, FIG. 11, etc., in a plan view, the green pixel electrode PEg may be positioned relatively closer to the blue pixel electrode PEb than to the red pixel electrode PEr. For example, in a plan view, the center of the green pixel electrode PEg may be located between the center of the red pixel electrode PEr and the center of the blue pixel electrode PEb. In the pixel repaired in the manner described above, the additional connection electrode ACE may be disposed between the green pixel electrode PEg and the blue pixel electrode PEb.

For reference, after the dummy connection line DCLg' is electrically connected to the green data line DLg, and the blue data connection line DCLb is separated into the two portions as shown in FIG. 14, the blue pixel electrode PEb may be separated into two portions as shown in FIG. 11. In another embodiment, after the blue pixel electrode PEb is separated into the two portions as shown in FIG. 11, the dummy connection line DCLg' may be electrically connected to the green data line DLg, and the blue data connection line DCLb may be separated into the two portions, as shown in FIG. 14. However, the embodiments are not limited thereto, and various modifications are possible. For example, the blue pixel electrode PEb may be separated into two portions as shown in FIG. 11, the dummy connection line DCLg' may be electrically connected to the green data line DLg, and the blue data connection line DCLb may be separated into the two portions as shown in FIG. 14, and then the additional connection electrode ACE may be formed using the inkjet printing method or the like, as shown in FIG. 11.

FIG. 15 is a schematic conceptual diagram illustrating an image that the display panel 10 may display. Each of the pixels may include the red subpixel (R), the green subpixel (G), and the blue subpixel (B) as described above. FIG. 15 is a conceptual diagram, and the positions of the subpixels within each pixel are not limited to those shown in FIG. 15 and may be modified in various ways.

In FIG. 15, subpixels that emit light are shown with hatching, and subpixels that do not emit light are shown without hatching. For example, in the case of red subpixels belonging to the pixels in the first column, red subpixels that emit the red light and red subpixels that do not emit light may be positioned alternately along the first direction (or y-axis direction). And for the red subpixels belonging to the pixels in the first row, the red subpixels that emit the red light and the red subpixels that do not emit light may be positioned alternately along the second direction (or x-axis direction). This may also be applied to the green subpixels and blue subpixels. However, each of the pixels to which the green subpixels that emit the green light belong includes the red subpixel that does not emit the red light and the blue subpixel that does not emit the blue light.

FIG. 15 shows the image at a certain moment displayed by the display panel 10 and the electronic apparatus including the display panel 10, and the state of each subpixel may alternate over time between a light-emitting state and a non-light-emitting state.

FIG. 16 is a schematic graph illustrating data signals applied to the display panel 10 to display the image of FIG. 15. FIG. 16 is a schematic graph illustrating a data signal Rdata applied to the red subpixel, a data signal Gdata applied to the green subpixel, and a data signal Bdata applied to the blue subpixel of a pixel included in the display panel 10, as time T goes by.

As shown in FIG. 16, the red subpixel and the blue subpixel included in a pixel may emit light simultaneously or may not emit light simultaneously. The green subpixel included in that pixel does not emit green light in case that the red subpixel and the blue subpixel included in that pixel emit light, and emits green light in case that the red subpixel and the blue subpixel included in that pixel do not emit light. Accordingly, as shown in FIG. 16, the phase of the data signal Gdata applied to the green subpixel included in one pixel is opposite to the phase of the data signal Rdata applied to the red subpixel included in that pixel and the phase of the data signal Bdata applied to the blue subpixel included in the pixel. For example, if, in a set of data lines including the red data line DLr, the green data line DLg, and the blue data line DLb that are electrically connected to one pixel, the green data line DLg is disposed between the red data line DLr and the blue data line DLb, the green data line DLg may be affected by the red data line DLr and the blue data line DLb due to coupling, etc. As a result, the user may recognize the image displayed by the display panel 10 and the electronic apparatus including the display panel 10 as an image having a stain-like pattern extending in the first direction (or y-axis direction) as the green data line DLg extends, not as a white image. This is because, as mentioned above, the proportion of the blue light in the white light is about 10%, the proportion of the red light in the white light is about 20%, and the proportion of the green light in the white light is about 70%.

However, as described above, in the case of the display panel 10 and the electronic apparatus including the display panel 10 according to the embodiment, one of the red data line DLr or the blue data line DLb in the data line set may be positioned at the center of the data line set. Accordingly, in case that displaying an extreme image as shown in FIG. 15, it is possible to implement the display panel 10 and the electronic apparatus including the display panel 10 that may display a high-quality image.

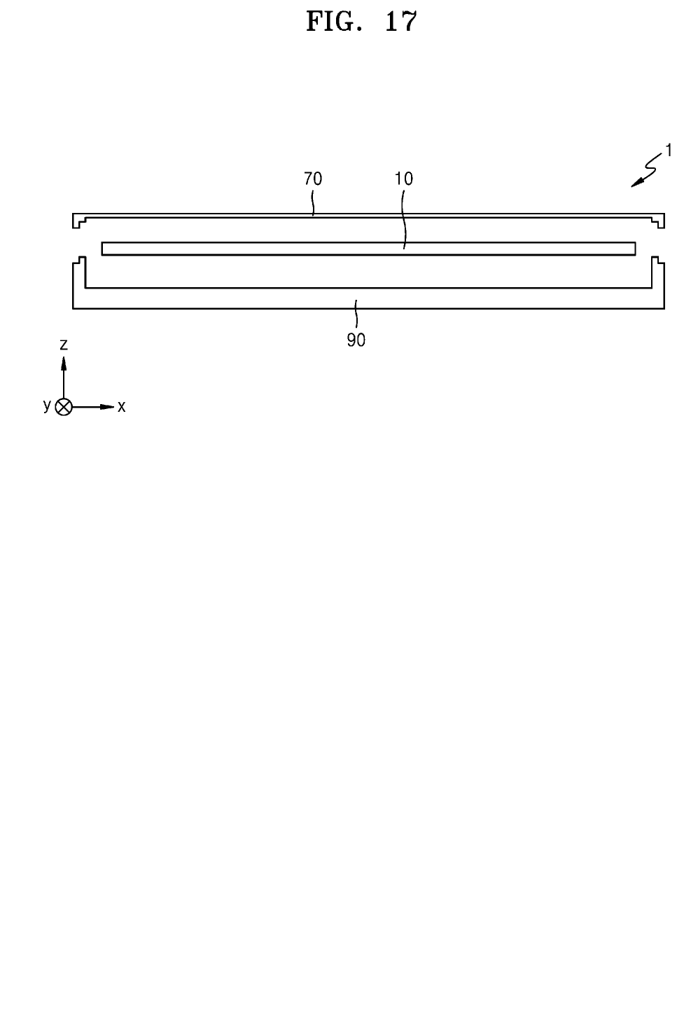

The description has focused on the display panel 10, however, embodiments are not limited thereto. For example, as shown in FIG. 17, which is a schematic conceptual diagram illustrating an electronic apparatus according to one or more embodiments, an electronic apparatus 1 may include any one of the display panels 10 described above.

The electronic apparatus 1 according to one or more embodiments may be an apparatus for displaying moving images or still images. The apparatus may be a portable electronic apparatus, such as a mobile phone, a smartphone, a tablet personal computer (PC), a mobile communication terminal, an electronic notebook, an electronic book, a portable multimedia player (PMP), a navigation, or an ultra-mobile PC (UMPC), or may be a variety of products, such as televisions, laptops, monitors, billboards, or an Internet of things (IoT)-linked device. In another embodiment, the electronic apparatus 1 according to an embodiment may also be a wearable device such as a smart watch, a watch phone, a glasses-type display, or a head-mounted display (HMD). In another embodiment, the electronic apparatus 1 according to an embodiment may also be an instrument panel of a vehicle, a center fascia of a vehicle or a center information display (CID) disposed on a dashboard, a room mirror display replacing a side view mirror of a vehicle, or a display disposed on the rear side of a front seat as an entertainment device for a passenger in the backseat of a vehicle.

The electronic apparatus 1 may include a cover window 70, a lower cover 90, and a display panel 10 interposed between the cover window 70 and the lower cover 90, such as the display panel 10 described above. The electronic apparatus 1 may further include additional elements such as a display circuit board, components, a main circuit board, and/or a battery, if necessary. The components may include a proximity sensor, a light sensor, an iris sensor, a facial recognition sensor, and/or a camera (or image sensor). Most of these additional elements may be housed in the space between the cover window 70 and the lower cover 90.

The cover window 70 may be disposed over the display panel 10 to cover an upper surface of the display panel 10. The cover window 70 may protect the upper surface of the display panel 10. The cover window 70 may include a transparent cover unit corresponding to (or overlapping) the display panel 10 and a light-shielding cover unit surrounding the transparent cover unit. The light-shielding cover unit may include an opaque material (e.g., a colored opaque material) that blocks light. The light-shielding cover unit may include a pattern which is visible to the user in case that no image is displayed.

The lower cover 90 may form the exterior shape of the electronic apparatus 1, and may have an opening that exposes a portion of the display panel 10. The lower cover 90 may be assembled with the display panel 10 such that the display area of the display panel 10 is exposed through the opening of the lower cover 90. The lower cover 90 may be positioned such that the display panel 10 is interposed between the lower cover 90 and the cover window 70. The lower cover 90 may include plastic, metal, or both plastic and metal.

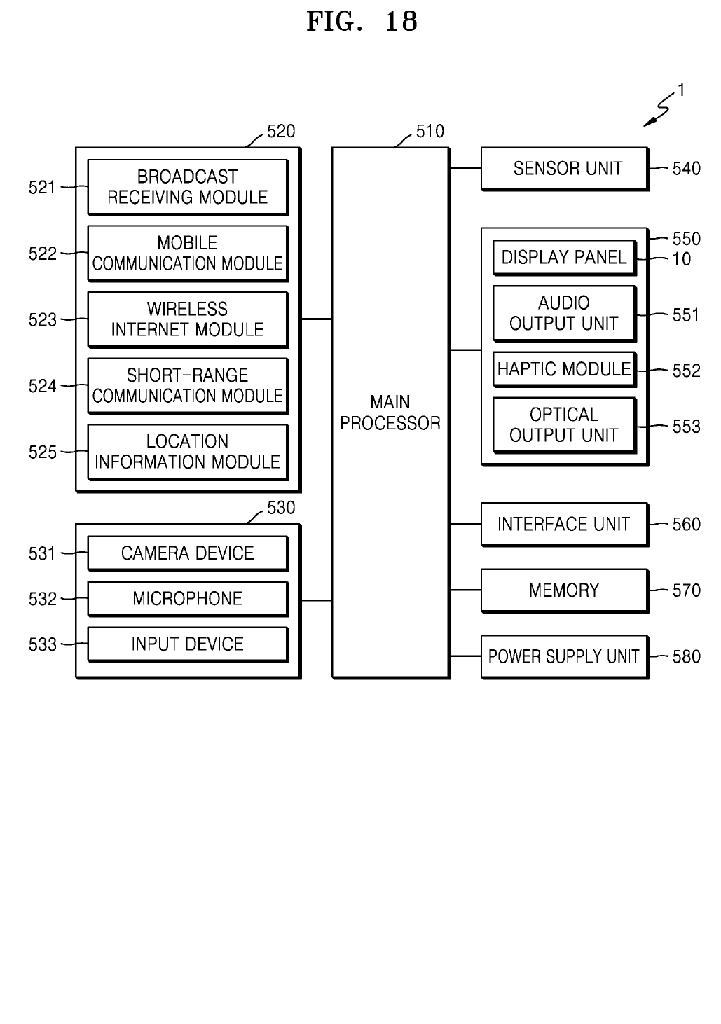

FIG. 18 is a schematic block diagram illustrating the electronic apparatus 1 of FIG. 17. As shown in FIG. 18, the electronic apparatus 1 may include a main processor 510, a wireless communication unit 520, an input unit 530, a sensor unit 540, an output unit 550, an interface unit 560, a memory 570, and/or a power supply unit 580.

The main processor 510 may control all functions of the electronic apparatus 1. For example, the main processor 510 may output digital video data to the data driver through the display circuit board so that an image is displayed on the display panel 10. The main processor 510 may receive input of sensing data from the touch sensor driving unit. The main processor 510 may determine whether a user's touch is received according to the sensing data, and execute an operation corresponding to a direct touch or proximity touch of the user. The main processor 510 may be an application processor, a central processing unit, or a system chip, each of which include an IC.

The wireless communication unit 520 may include at least one of a broadcast receiving module 521, a mobile communication module 522, a wireless Internet module 523, a short-range communication module 524, or a location information module 525.

The broadcast receiving module 521 may receive broadcast signals and/or broadcast-related information from an external broadcast management server via a broadcast channel. The broadcast channel may include satellite channels and terrestrial channels.

The mobile communication module 522 may transmit and receive wireless signals to and from at least one of, an external terminal, a server on a mobile communication network, or a base station established according to technology standards or communication methods for mobile communication (e.g., Global System for Mobile Communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signal may include voice call signals, video call signals, or various forms of data according to text/multimedia message transmission and reception.

The wireless Internet module 523 is a module for wireless Internet connection. The wireless Internet module 523 may transmit and receive wireless signals in a communication network according to wireless Internet technologies. The wireless Internet technology may include, for example, Wireless LAN (WLAN), Wireless-Fidelity (Wi-Fi), Wi-Fi Direct, Digital Living Network Alliance (DLNA), and the like.

The short-range communication module 524, which ensures short-range communication, may support short-range communication by using at least one of Bluetooth, Radio Frequency Identification (RFID), Infrared Data Association (IrDA), Ultra-Wideband (UWB), ZigBee, Near Field Communication (NFC), Wi-Fi, Wi-Fi Direct, or Wireless Universal Seral Bus (USB) technologies. The short-range communication module 524 may support wireless communication between the electronic apparatus 1 and a wireless communication system, between the electronic apparatus 1 and another electronic apparatus, or the electronic apparatus 1 and a network where another electronic apparatus (or external server) is located, through wireless area networks. The wireless area networks may be wireless personal area networks. The other electronic apparatus may be a wearable device capable of mutually exchanging data with (or linking with) the electronic apparatus 1.

The location information module 525, which is a module for obtaining a location (or current location) of the electronic apparatus 1, may include a global positioning system (GPS) module or a Wi-Fi module.

The input unit 530 may include an image input unit such as the camera device 531 for inputting an image signal, an audio input unit such as a microphone 532 for inputting an audio signal, and an input device 533 for receiving information (or input) from a user. The camera device 531 may process image frames, such as still images or moving images, obtained by an image sensor in a video call mode or shooting mode. The processed image frames may be displayed on the display panel 10 or stored in the memory 570. The microphone 532 may process external audio signals into electrical sound data. The processed sound data may be variously used according to a function being performed (or application being run) in the electronic apparatus 1.

The main processor 510 may control an operation of the electronic apparatus 1 to correspond to (or overlap) information received via the input device 533. The input device 533 may include a mechanical input means, such as a button positioned on the rear surface or side surface of the electronic apparatus 1, a dome switch, a jog wheel, or a jog switch, or a touch input means. The touch input means may include a touch screen layer of the display panel 10.

The sensor unit 540 may include one or more sensors that senses at least one of information within the electronic apparatus 1, surrounding environment information of the electronic apparatus 1, or user information, and generate a sensing signal corresponding thereto. Based on this sensing signal, the main processor 510 may control driving or operation of the electronic apparatus 1 or perform data processing, functions, or operations associated with applications installed in the electronic apparatus 1. The sensor unit 540 may be a proximity sensor, an illumination sensor, or a facial recognition sensor. The sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. The sensor unit 540 may include an environmental sensor or a chemical sensor. The environmental sensors may include, for example, a barometer, a hygrometer, a thermometer, a radiation detection sensor, a heat detection sensor, and/or a gas detection sensor. Chemical sensors may include, for example, an electronic nose, a healthcare sensor, and/or a biometric recognition sensor.

The output unit 550 may generate an output associated with vision, hearing, and tactile sensations, and may include at least one of the display panel 10, an audio output unit 551, a haptic module 552, or an optical output unit 553.

The display panel 10 may display (or output) information processed in the electronic apparatus 1. For example, the display panel 10 may display execution screen information of an application driven in the electronic apparatus 1, or to display user interface (UI) or graphic user interface (GUI) information according to the execution screen information. The display panel 10 may include a display layer for displaying images and a touch screen layer for detecting a touch input of a user. Therefore, the display panel 10 may function as one of the input devices 533 that provide an input interface between the electronic apparatus 1 and the user, and at the same time, may function as the output unit 550 that provide an output interface between the electronic apparatus 1 and the user.

The audio output unit 551 may output audio data received from the wireless communication unit 520 or stored in the memory 570 in a call signal reception mode, a call mode or recording mode, a speech recognition mode, a broadcast reception mode, or the like. The audio output unit 551 may output audio signals associated with functions performed in the electronic apparatus 1, such as call signal reception sound, message reception sound, or the like. The audio output unit 551 may include a receiver or a speaker. At least one of the receiver or the speaker may be a sound generation device which is attached below the display panel 10 and vibrate the display panel 10 to output sound. The sound generation device may be a piezoelectric element, or piezoelectric actuator, that contracts and expands in response to an electric signal, or an exciter that generates a magnetic force by using a voice coil and vibrates the display panel 10.

The haptic module 552 may generate various tactile effects that may be felt by the user. The haptic module 552 may provide vibration to the user as a tactile effect. The haptic module 552 may not only transfer a tactile effect through direct contact, but also may be implemented such that the user may feel the tactile effect through muscle sensations in the fingers or arms.

The optical output unit 553 may output a signal for notifying the user of the occurrence of an event by using light from a light source. Examples of events occurring in the electronic apparatus 1 may include receiving a message, receiving a call signal, receiving a missed call, an alarm, a schedule alarm, a schedule reminder, receiving an e-mail, receiving information through an application, and the like. The signal output from the optical output unit 553 may be implemented as the electronic apparatus 1 emits light of a single color or multiple colors from the front or rear thereof. The outputting of the signal may be terminated in case that the electronic apparatus 1 detects the user's identification of the event.

The interface unit 560 serves as a passageway for various types of external devices electrically connected to the electronic apparatus 1. The interface unit 560 may include at least one of a wired/wireless headset port, an external charger port, a wired/wireless data port, a memory card port, a port connecting a device equipped with an identification module, an audio input/output (I/O) port, a video I/O port, or an earphone port. In case that the electronic apparatus 1 is electrically connected to an external device through the interface unit 560, the electronic apparatus 1 may perform an appropriate control associated with the connected external device.

The memory 570 may store data supporting various functions of the electronic apparatus 1. The memory 570 may store multiple application programs running on the electronic apparatus 1, data for an operation of the electronic apparatus 1, and instructions. At least some of multiple applications may be downloaded from an external server through wireless communication. The memory 570 may store an application for an operation of the main processor 510, or may temporarily store input/output data, e.g., data such as a phonebook, messages, still images, and moving images. The memory 570 may store haptic data for vibration of various patterns provided to the haptic module 552, and audio data associated with various sounds provided to the audio output unit 551.

The memory 570 may include a storage medium of at least one type from among a flash memory type, a hard disk type, a solid state disk type (SSD) type, a silicon disk drive (SDD) type, a multimedia card micro type, a card-type memory (e.g., secure digital (SD) or extreme digital (XD) memory), random access memory (RAM), static RAM (SRAM), read-only memory (ROM), electrically erasable programmable ROM (EEPROM), programmable ROM (PROM), magnetic memory, a magnetic disk, or an optical disk.

Under the control of the main processor 510, the power supply unit 580 may receive external power and/or internal power and supply power to each of elements included in the electronic apparatus 1. The power supply unit 580 may include the battery. The power supply unit 580 may have a connection port, and the connection port may be configured as an example of the interface unit 560 to which an external charger supplying power for battery charging is electrically connected. In another embodiment, the power supply unit 580 may charge the battery in a wireless manner.

The display panel according to one or more embodiments described above includes the pixel circuit including the red pixel circuit, the green pixel circuit, and the blue pixel circuit, and the data line set including the red data line, the green data line, and the blue data line, and emits red light by the red pixel circuit, green light by the green pixel circuit, and blue light by the blue pixel circuit. However, embodiments are not limited thereto.

For example, a display panel according to one or more embodiments may include a pixel circuit including a cyan pixel circuit, a yellow pixel circuit, and a purple pixel circuit, and a data line set including a cyan data line, a yellow data line, and a purple data line, and may emit cyan light by the cyan pixel circuit, yellow light by the yellow pixel circuit, and purple light by the purple pixel circuit.

In case that the display panel 10 that displays an image by emitting the cyan light, the yellow light, and/or the purple light from pixels and an electronic apparatus including the display panel 10 display a white image, the proportion of the yellow light in the white light is the largest and the proportion of the purple light in the white light is the smallest. Accordingly, the aforementioned description about the green pixel circuit and the green data line, etc. may be replaced with a description about the yellow pixel circuit and the yellow data line, etc., the aforementioned description about the blue pixel circuit and the blue data line, etc. may be replaced with a description about the purple pixel circuit and the purple data line, etc., and the aforementioned description about the red pixel circuit and the red data line, etc. may be replaced with a description about the cyan pixel circuit and the cyan data line, etc.

In another embodiment, the aforementioned red pixel circuit may be referred to as a first color pixel circuit, the aforementioned green pixel circuit may be referred to as a second color pixel circuit, the aforementioned blue pixel circuit may be referred to as a third color pixel circuit, the aforementioned red data line may be referred to as a first color data line, the aforementioned green data line may be referred to as a second color data line, the aforementioned blue data line may be referred to as a third color data line, the aforementioned red light may be referred to as a first color light, the aforementioned green light may be referred to as a second color light, the aforementioned blue light may be referred to as a third color light, the aforementioned red data connection line may be referred to as a first color data connection line, the aforementioned green data connection line may be referred to as a second color data connection line, the aforementioned blue data connection line may be referred to as a third color data connection line, the aforementioned red pixel electrode may be referred to as a first color pixel electrode, the aforementioned green pixel electrode may be referred to as a second color pixel electrode, and the aforementioned blue pixel electrode may be referred to as a third color pixel electrode.

Among the first color light emitted by the first color pixel circuit, the second color light emitted by the second color pixel circuit, and the third color light emitted by the third color pixel circuit, the proportion of the second color light in the white light would be largest. The proportion of the third color light in the white light would be smallest. For example, the aforementioned description about the red pixel circuit, the red data line, the red data connection line, and the red pixel electrode, etc. may be applied to the description about the first color pixel circuit, the first color data line, the first color data connection line, and the first color pixel electrode, etc. Similarly, the aforementioned description about the green pixel circuit, the green data line, the green data connection line, and the green pixel electrode, etc. may be applied to the description about the second color pixel circuit, the second color data line, the second color data connection line, and the second color pixel electrode, etc. Likewise, the aforementioned description about the blue pixel circuit, the blue data line, the blue data connection line, and the blue pixel electrode, etc. may be applied to the description about the third color pixel circuit, the third color data line, the third color data connection line, and the third color pixel electrode, etc.

For example, the above-described embodiments may be understood as a case where the first color light is the red light, the second color light is the green light, and the third color light is the blue light. Also, as described above, the embodiment may be applied to a case where the first color light is the cyan light, the second color light is the yellow light, and the third color light is the magenta light.

According to one or more embodiments as described above, a display panel and an electronic apparatus, in which a high-quality image is displayed, can be implemented. However, the scope of the disclosure is not limited to the above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a pixel circuit including a first color pixel circuit, a second color pixel circuit, and a third color pixel circuit; and
a data line set disposed on one side of the pixel circuit and including a first color data line, a second color data line, and a third color data line each extending in a first direction,
wherein among first color light emitted by the first color pixel circuit, second color light emitted by the second color pixel circuit, and third color light emitted by the third color pixel circuit, the second color light includes highest proportion in white light, and
one of the first color data line and the third color data line in the data line set is disposed at a center of the data line set.

2. The display panel of claim 1, wherein among the first color data line, the second color data line, and the third color data line, the second color data line is disposed closest to the pixel circuit.

3. The display panel of claim 1, wherein the second color data line includes a plurality of protrusions that protrude in a direction crossing the first direction in a portion corresponding to the pixel circuit.

4. The display panel of claim 3, wherein the third color light includes lowest proportion in the white light, one of the plurality of protrusions is disposed to overlap the second color pixel circuit, and another one of the plurality of protrusions is disposed to overlap the third color pixel circuit.

5. The display panel of claim 1, wherein the second color data line includes two protrusions protruding in a direction crossing the first direction in a portion corresponding to the pixel circuit.

6. The display panel of claim 5, wherein the third color light includes lowest proportion in the white light, one of the two protrusions of the second color data line is disposed to overlap the second color pixel circuit, and
the other of the two protrusions of the second color data line is disposed to overlap the third color pixel circuit.

7. The display panel of claim 1, wherein the first color pixel circuit includes a first color data connection line electrically connecting a thin film transistor of the first color pixel circuit to the first color data line,
the second color pixel circuit includes a second color data connection line electrically connecting a thin film transistor of the second color pixel circuit to the second color data line, and
the third color pixel circuit includes a third color data connection line electrically connecting a thin film transistor of the third color pixel circuit to the third color data line.

8. The display panel of claim 1, wherein the third color light includes lowest proportion in the white light,
the first color pixel circuit includes a first color data connection line electrically connecting a thin film transistor of the first color pixel circuit to the first color data line,
the second color pixel circuit includes a second color data connection line electrically connecting a thin film transistor of the second color pixel circuit to the second color data line, and
the third color pixel circuit includes a third color data connection line electrically connecting a thin film transistor of the third color pixel circuit to the second color data line.

9. The display panel of claim 8, further comprising:
a dummy electrode on a layer on which the third color data connection line is disposed, having an isolated shape, and electrically connected to the third color data line.

10. The display panel of claim 8, further comprising:
a first color pixel electrode electrically connected to the first color pixel circuit;
a second color pixel electrode electrically connected to the second color pixel circuit; and
an additional connection electrode electrically connected to the third color pixel circuit and the second color pixel electrode.

11. The display panel of claim 10, further comprising:
a third color pixel electrode on a layer on which the additional connection electrode is disposed, spaced apart from the additional connection electrode, and having an isolated shape.

12. The display panel of claim 11, wherein, in a plan view, the second color pixel electrode is closer to the third color pixel electrode than to the first color pixel electrode.

13. The display panel of claim 11, wherein
the additional connection electrode is disposed between the second color pixel electrode and the third color pixel electrode, and
among the first color data line, the second color data line, and the third color data line, the second color data line is disposed farthest from the pixel circuit.

14. The display panel of claim 13, wherein the first color pixel circuit includes a first color data connection line electrically connecting a thin film transistor of the first color pixel circuit to the first color data line,
the second color pixel circuit includes a second color data connection line electrically connecting a thin film transistor of the second color pixel circuit to the second color data line, and
the third color pixel circuit includes a third color data connection line electrically connecting a thin film transistor of the third color pixel circuit to the third color data line, and a dummy connection line electrically connected to the thin film transistor of the third color pixel circuit and extending over the second color data line.

15. The display panel of claim 13, wherein the third color light includes lowest proportion in the white light,
the first color pixel circuit includes a first color data connection line electrically connecting a thin film transistor of the first color pixel circuit to the first color data line,
the second color pixel circuit includes a second color data connection line electrically connecting a thin film transistor of the second color pixel circuit to the second color data line, and
the third color pixel circuit includes a dummy connection line electrically connecting a thin film transistor of the third color pixel circuit to the second color data line.

16. The display panel of claim 15, further comprising:
a third color data connection line on a layer on which the dummy connection line is disposed, having an isolated shape, and electrically connected to the third color data line;
a first color pixel electrode electrically connected to the first color pixel circuit;
a second color pixel electrode electrically connected to the second color pixel circuit; and
an additional connection electrode electrically connected to the third color pixel circuit and the third color pixel electrode.

17. The display panel of claim 16, further comprising:
a third color pixel electrode on a layer on which the additional connection electrode is disposed, spaced apart from the additional connection electrode, and having an isolated shape.

18. The display panel of claim 17, wherein, in a plan view, the second color pixel electrode is disposed closer to the third color pixel electrode than to the first color pixel electrode, and
the additional connection electrode is disposed between the second color pixel electrode and the third color pixel electrode.

19. The display panel of claim 1, wherein
the first color light includes red light,
the second color light includes green light, and
the third color light includes blue light.

20. An electronic apparatus comprising:
a display panel including:
a pixel circuit including a first color pixel circuit, a second color pixel circuit, and a third color pixel circuit; and
a data line set disposed on one side of the pixel circuit and including a first color data line, a second color data line, and a third color data line each extending in a first direction,
wherein, among first color light emitted by the first color pixel circuit, second color light emitted by the second color pixel circuit, and third color light emitted by the third color pixel circuit, the second color light includes highest proportion in white light, and
one of the first color data line and the third color data line in the data line set is disposed at a center of the data line set; and
a lower cover forming an exterior of the electronic apparatus and having an opening exposing a portion of the display panel.
